(19) United States
(12) Patent Application Publication
(10) Pub. No.: US 2026/0040438 A1
(43) Pub. Date: Feb. 5, 2026

(54) CONDUCTIVE AND CORROSIVE-RESISTANT LIQUID METAL COMPOSITIONS AND ELECTRONIC DEVICES USING SAME

(71) Applicant: Meta Platforms Technologies, LLC, Menlo Park, CA (US)

(72) Inventors: Omar Awartani, Redmond, WA (US); Marcos Antonio Santana Andrade, JR., Seattle, WA (US); Darpan Shukla, Raleigh, NC (US); Behnam Sadri, Redmond, WA (US); Wenyang Pan, Redmond, WA (US); Benjamin Cook, Woodinville, WA (US); Thomas John Farrell Wallin, Redmond, WA (US)

(21) Appl. No.: 19/288,670

(22) Filed: Aug. 1, 2025

Related U.S. Application Data
(60) Provisional application No. 63/679,060, filed on Aug. 2, 2024.
(60) Provisional application No. 63/679,045, filed on Aug. 2, 2024.

(51) Int. Cl. H05K 1/02; C22C 49/04; H05K 1/03; H05K 1/09; H05K 1/18; H05K 3/12

(52) U.S. Cl. CPC H05K 1/0283; C22C 49/04; H05K 1/095; H05K 1/185; H05K 1/189; H05K 3/1283; H05K 1/0326; H05K 2201/0145; H05K 2201/0158; H05K 2201/0311

(57) ABSTRACT

A method of the subject technology includes forming a first circuit component at a first portion of a deformable substrate and forming a second circuit component at a second portion of the deformable substrate. The method further includes electronically coupling the first circuit component and the second circuit component using traces comprising a formulation including a liquid Ga-based alloy and a metal filler.

### CROSS REFERENCE TO RELATED APPLICATIONS

The present disclosure is related and claims priority under 35 USC § 119 (c) to U.S. Provisional Application No. 63/679,045, entitled “CORROSIVE RESISTANT METAL COMPOSITIONS AND DEVICES USING SAME,” filed on Aug. 2, 2024 and U.S. Provisional Application No. 63/679,060, entitled “CONDUCTIVE LIQUID METAL COMPOSITIONS AND ELECTRONIC DEVICES USING SAME,” filed on Aug. 2, 2024, the contents of which are herein incorporated by reference, in their entirety, for all purposes.

### TECHNICAL FIELD

The present disclosure generally relates to Liquid metal compositions, and more particularly, to conductive and corrosive-resistant liquid metal compositions and electronic devices using such compositions.

### BACKGROUND

Liquid metal (LM) inks are very promising for making printable, highly stretchable, and conductive traces within electronic circuits. However, conventional liquid metals, such as eutectic gallium-indium (EGaIn), only have a fraction of the conductivity of an ideal metal, such as copper. As such, structures formed from EGaIn required more volume or surface area to meet the same resistance (and voltage drop) of a copper trace counterpart.

Furthermore, conventional liquid metals, such as EGaIn, are vulnerable to corrosion (e.g., oxidation) of the liquid metal, such as when the liquid metal is exposed to a high temperature and/or high humidity, such as those above typical room conditions. Under these conditions, water vapor in the environment permeates into structures containing the liquid metal and oxidizes the liquid metal, such as by forming gallium oxide hydroxide (GaOOH) and hydrogen gas. Moreover, the hydrogen gas becomes trapped into the oxide material and/or the structure, resulting in an undesirable foam-like structure, such as that shown in FIG. 17A. This oxidation and foam-like structure reduces the ability of the liquid metal to conduct electricity when a strain is applied to the liquid metal.

### SUMMARY

According to some aspects, a method of the subject technology includes a method of the subject technology includes forming a first circuit component at a first portion of a deformable substrate and forming a second circuit component at a second portion of the deformable substrate. The method further includes electronically coupling the first circuit component and the second circuit component using traces comprising a formulation including a liquid Ga-based alloy and a metal filler.

According to other aspects, a device of the subject technology includes an electronic device including a first circuit component formed at a first portion of a deformable substrate and a second circuit component formed at a second portion of the deformable substrate. The electronic device further includes a plurality of traces to electronically couple the first circuit component to the second circuit component. The traces comprise a formulation including a liquid Ga-based alloy and a metal filler.

According to yet other aspects, a method of the subject technology includes forming a composition by providing a liquid solution including a Ga-based alloy including nanowires and mixing nanoparticles of a barrier material and a micro-powder with the liquid solution.

According to yet other aspects, a method of the subject technology includes forming a first circuit component at a first portion of a deformable substrate, forming a second circuit component at a second portion of the deformable substrate. The method further includes tracing out at least one of a line or a via to couple the first circuit component and the second circuit component, with a composition comprising a solution with a polymer binder dissolved in at least one solvent and a liquid metal. Subsequent to the tracing out, the first polymer polymerizes thereby forming the line or the via that couples, and electronically connects, the first circuit component and the second circuit component

### BRIEF DESCRIPTION OF THE DRAWINGS

To easily identify the discussion of any particular element or act, the most significant digit or digits in a reference number refer to the FIG. number in which that element is first introduced.

FIG. 1 illustrates a block diagram schematically illustrating an electronic device in accordance with some embodiments of the present disclosure.

FIG. 2 illustrates a process of forming a composition in accordance with some embodiments of the present disclosure.

FIG. 3 is a chart illustrating conductivity of a variety of compositions with various barrier metals in accordance with some embodiments of the present disclosure.

FIG. 4 is a chart illustrating a conductivity and a resistance of a composition with varying weight percent (wt %) of a barrier metal with a liquid gallium (Ga) based alloy, in accordance with some embodiments of the present disclosure.

FIGS. 5, 6, 7, 8, 9, 10, 11, and 12 illustrate charts of a conductivity of a composition with varying volume percent (% % v/v) of a barrier metal with a liquid Ga-based alloy, in accordance with some embodiments of the present disclosure.

FIGS. 13A, 13B, 13 C and 13D illustrate cross-sectional views of structures of electronic devices and corresponding traces in accordance with some embodiments of the present disclosure.

FIG. 14 is a cross-sectional view of a trace embedded in a stretchable or flexible substrate of an electronic device, in accordance with some embodiments of the present disclosure.

FIG. 15 is a cross-sectional view of a trace embedded in a stretchable or flexible substrate of an electronic device, in accordance with some embodiments of the present disclosure.

FIG. 16 is a cross-sectional view of a trace embedded in a stretchable or flexible substrate of an electronic device, in accordance with some embodiments of the present disclosure.

FIGS. 17A, 17B, 17C illustrate charts depicting a resistance of a trace embedded in a stretchable or flexible substrate of an electronic device.

FIG. 18 is a cross-sectional view of a core-shell particle of a composition, in accordance with some embodiments of the present disclosure.

FIG. 19 is a flowchart illustrating a method for manufacturing an electronic device, in accordance with some embodiments of the present disclosure.

FIG. 20 illustrates exemplary logic functions that can be implemented into an electronic device, in accordance with some embodiments of the present disclosure.

FIG. 21 illustrates an electronic device, in accordance with some embodiments of the present disclosure.

FIG. 22 is a bar chart illustrating drying times of solution drops on a glass slide at lab temperature, in accordance with some embodiments of the present disclosure.

FIGS. 23A, 23B, 23C and 23D are images of traces made of exemplary compositions, in accordance with some embodiments of the present disclosure.

FIGS. 24A and 24B are graphs showing a resistance of a first trace measured at 100% cyclic strain, in accordance with some embodiments of the present disclosure.

FIGS. 25A, 25B and 25C are graphs showing a resistance of a second trace measured at 100% cyclic strain, in accordance with some embodiments of the present disclosure.

FIG. 26 is a graph showing a resistance of a third trace measured at 100% cyclic strain, in accordance with some embodiments of the present disclosure.

FIGS. 27A and 27B are graphs showing a resistance of a fourth trace measured at 100% cyclic strain, in accordance with some embodiments of the present disclosure.

FIG. 28 is a flowchart illustrating a method for manufacturing an electronic device, in which optional embodiments are indicated by dashed boxes, in accordance with some embodiments of the present disclosure.

FIG. 29 is a flowchart illustrating a method for manufacturing an exemplary circuit of an electronic device, in accordance with some embodiments of the present disclosure.

FIG. 30 is a flowchart illustrating a method for manufacturing another exemplary circuit of an electronic device, in accordance with some embodiments of the present disclosure.

In one or more implementations, not all of the depicted components in each FIG. may be required, and one or more implementations may include additional components not shown in a figure. Variations in the arrangement and type of the components may be made without departing from the scope of the subject disclosure. Additional components, different components, or fewer components may be utilized within the scope of the subject disclosure.

### DETAILED DESCRIPTION

The detailed description set forth below describes various configurations of the subject technology and is not intended to represent the only configurations in which the subject technology may be practiced. The detailed description includes specific details for the purpose of providing a thorough understanding of the subject technology. Accordingly, dimensions may be provided in regard to certain aspects as non-limiting examples. However, it will be apparent to those skilled in the art that the subject technology may be practiced without these specific details. In some instances, well-known structures and components are shown in block diagram form in order to avoid obscuring the concepts of the subject technology.

It is to be understood that the present disclosure includes examples of the subject technology and does not limit the scope of the included clauses. Various aspects of the subject technology will now be disclosed according to particular but non-limiting examples. Various embodiments described in the present disclosure may be carried out in different ways and variations, and in accordance with a desired application or implementation.

In the following detailed description, numerous specific details are set forth to provide a full understanding of the present disclosure. It will be apparent, however, to one ordinarily skilled in the art, that embodiments of the present disclosure may be practiced without some of the specific details. In other instances, well-known structures and techniques have not been shown in detail so as not to obscure the disclosure.

Some aspects of the subject disclosure are directed to conductive and corrosive-resistant liquid metal compositions and electronic devices using such compositions, as discussed herein. One aspect of the present disclosure provides a desired liquid metal that has beneficial conductive and corrosive-resistant properties. For instance, in some embodiments, a composition of a trace in a plurality of traces of an electronic device has a conductivity greater than 3.4×10⁶ Siemens per meter (S/m), which allows for forming the trace with a reduced cross-sectional area of LM traces, which, in turn, increases a number of the plurality of lines formed on or within a substrate (e.g., decreases a spacing between adjacent lines). In some embodiments, the composition allows for reducing a thickness of the trace, which, in turn, reduces a height of the electronic device that contributes to increased bending stiffness and/or higher bending strain for other materials in the electronic device, such as one or more pyrolytic graphite sheets (PGS) utilized for thermal management. In some embodiments, the composition allows for improved conductivity, which, in turn, reduces real insertion loss for high-speed and radio frequency (RF) information transmitted through the trace.

Another aspect of the present disclosure provides an electronic device. The electronic device includes a plurality of traces. A trace in the plurality of traces is formed by a composition that includes a liquid gallium (Ga) based alloy with between 0.5% v/v and 7.0% v/v of a barrier metal. The barrier metal is aluminum, bismuth, gold, hafnium, silver, titanium, or tungsten, an alloy thereof, or a combination thereof. Moreover, the composition has a conductivity of at least 3.4×10⁶ Siemens per meter (S/m).

Yet another aspect of the present disclosure is directed to providing a method of manufacturing an electronic device. The method includes forming a first circuit component at a first portion of a deformable substrate. The method further includes forming a second circuit component at a second portion of the deformable substrate. Additionally, the method includes tracing out a line or via that couples the first circuit component and second circuit component, with a composition of the present disclosure.

One aspect of the present disclosure provides an optimized solvent-based liquid metal composition including a solution and a liquid metal mixed with the solution. The solution includes at least one solvent and a polymeric binder dissolved in the solvent. In some embodiments, additionally or optionally, the composition includes a metallic filler. The composition is tailored to extend the decap time while maintaining other beneficial properties, such as viscosity, electrical conductivity, or the like, to permit the use of the composition in various printing techniques. In some embodiments, the composition has a decap time of at least 1 minute, at least 2 minutes, at least 5 minutes, at least 15 minutes, at least 20 minutes, at least half an hour, at least 1 hour, at least 2 hours, at least 3 hours, at least 4 hours, at least 5 hours, or greater than 5 hours.

In certain embodiments, the solvent includes a first solvent and the first solvent includes TXIB. In such embodiments, the polymeric binder can be any suitable polymer or polymer mixture, including but not limited to styrene isoprene styrene (SIS), styrene ethylene butylene styrene (SEBS), silicones or any combination thereof disclosed herein.

In some embodiments, the solvent includes the first solvent of about 100% by volume.

Alternatively, in some embodiments, the solvent is a solvent mixture including two, three, four or more than four solvents. For instance, the solvent includes a second solvent. In an embodiment, the second solvent is toluene. In another embodiment, the second solvent is THF, cycolohexane, xylene, decane, or octyle acelate. In some embodiments, the at least one solvent includes the first solvent at an amount from about 3% to about 5%, from about 5% to 10%, from about 10% to 20%, from about 30% to 40%, from about 40% to 50%, or more than 50% by volume. In an embodiment, the first solvent is TXIB, the second solvent is toluene, and TXIB is at an amount from about 2% to about 20% by volume of toluene.

In certain embodiments, the polymeric binder includes a first polymer, and the first polymer includes SEBS. In such embodiments, the at least one solvent can be any suitable solvent or solvent mixture, including but not limited to toluene, tetrahydrofuran (THF), cyclohexane, xylene, decane, octyle acelate, TXIB, or any combination thereof disclosed herein.

In some embodiments, the first polymer has a molecular weight within a range of about 50 kg/mol to 400 kg/mol. In some embodiments, the styrene content in the first polymer is within a range of about 10 wt % to about 45 wt % of the first polymer. In some embodiments, a styrene block in the first polymer has a molar mass within a range of about 50 kg/mol. In some embodiments, an ethylene/butylene ratio in the first polymer is within a range of about 2:10 to about 7:10. In some embodiments, the polymeric binder consists of only the first polymer.

Alternatively, in some embodiments, the polymeric binder is a mixture including two, three, four or more than four polymers. For instance, in some embodiments, the polymeric binder includes a second polymer. In an embodiment, the second polymer is cellulose, poly (vinyl alcohol), poly (acrylic acid), polyvinylidene fluoride, polyvinyl acetate-polyvinylpyrrolidone, poly (ethylene glycol), amine, silicone, styrene isoprene styrene (SIS), styrene ethylene, or any combination thereof. In some embodiments, the polymeric binder includes the first polymer at an amount of more than about 10 wt %, more than about 20 wt %, more than about 30 wt %, more than about 40 wt %, more than about 50 wt %, more than about 60 wt %, more than about 70 wt %, or more than about 80 wt % of the binder. For instance, when the polymeric binder includes the first polymer at an amount of 10 wt %, then 10 percent of the weight of the polymeric binder is attributed to the first polymer whereas the remaining 90 percent of the weight of the polymeric binder is attributable to one or more other polymers.

In some embodiments, considering the polymeric binder dissolved in the at least one solvent, the polymeric binder dissolved in at least one solvent is present in a weight percentage in the solvent that is from about 5 wt % to about 30 wt % with respect to the solvent into which the polymeric binder is mixed.

In some embodiments, the composition includes the liquid metal at an amount from about 50% to about 90% of the overall composition by weight. In some embodiments, the liquid metal is a Ga-based alloy. In some embodiments, the Ga-based alloy includes gallium at an amount of from about 50 wt % to about 85 wt % of the overall composition. In some embodiments, the Ga-based alloy includes gallium indium alloy, gallium tin alloy, gallium indium tin alloy, gallium indium tin zinc alloy, or any combination thereof.

In some embodiments, the metallic filler is in a form of microflakes, nanoflakes, microparticles, nanoparticles, nanowires, nanotubes, or a combination thereof. In some embodiments, the metallic filler is at an amount from about 10% to about 20%, from about 20% to 30%, from about 30% to about 40%, or from about 40% to about 50% by weight of the liquid metal. Thus, in the case where the metallic filler is 10% by weight of the liquid metal and the liquid metal is 50% of the overall weight of the composition, the metallic filler is 10% by weight of the liquid metal and 5% by weight of the overall composition at the time the composition is used for tracing. However, subsequent to the tracing, it is expected that the solvent will evaporate causing weight percentages to the overall composition to adjust accordingly. In some embodiments, the metallic filler includes silver, copper, gold, or a mixture thereof.

Another aspect of the present disclosure provides a method for manufacturing an electronic device that includes at least a first circuit component, a second circuit component, and a line or via made of a composition of the present disclosure that electrically connects the first and second circuit components. The method includes forming a first circuit component at a first portion of a deformable substrate, and forming a second circuit component at a second portion of the deformable substrate. In some embodiments the circuit includes a single layer on the substrate whereas in other embodiments the circuit comprises a plurality of layers (e.g., 2 or more, 3 or more 4, or more, 5 or more layers) stacked on the deformable substrate. In some embodiments, each of these layers is deformable.

The method also includes tracing out at least one line or at least one via that couples the first circuit component and second circuit component, with any of the compositions disclosed herein. For instance, in some embodiments, the first and second circuit components are formed on the same layer of a circuit, and a line is traced out to couple the first and second circuit components. Alternatively, in some embodiments, the first and second circuit components are formed on two different layers of the circuit, and a via is formed to couple the first and second circuit components. The line or via can be traced using, for instance, an extrusion-based additive manufacturing method such as direct printing techniques. Subsequent to the tracing, the polymeric binder or at least a portion of it polymerizes thereby forming the line or via that couples, and electrically connects, the first circuit component and second circuit component.

In some embodiments, the compositions of the present disclosure are tuned to a large range of decap times. For instance, in some embodiments, a composition of the present disclosure has a decap time of at least 1 minute, at least 2 minutes, at least 5 minutes, at least 15 minutes, at least 20 minutes, or greater than 20 minutes. In some embodiments, a composition of the present disclosure has a decap time of at least half an hour, at least 1 hour, at least 2 hours, at least 3 hours, at least 4 hours, at least 5 hours, or greater than 5 hours.

Additionally or optionally, the compositions of the present disclosure are tuned to have a suitable viscosity to suit different applications. For instance, in some embodiments, a composition of the present disclosure, at a temperature between 64 degrees Fahrenheit (° F.) and 72° F., has a viscosity between 0.5 Pascal seconds (Pa·s) and 3 Pa·s,

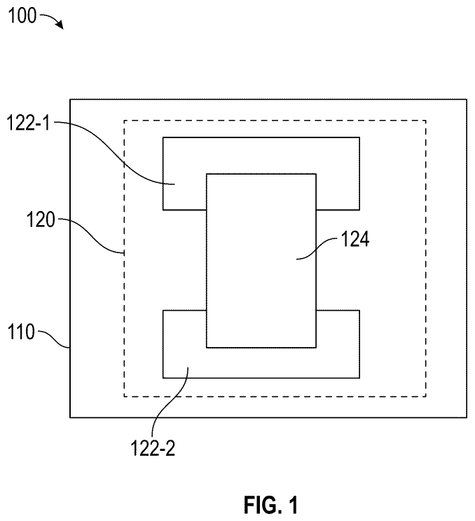

Turning now to the figures, FIG. 1 illustrates a block diagram schematically illustrating an electronic device 100 in accordance with some embodiments of the present disclosure. In some embodiments, the electronic device 100 includes a circuit that further includes two or more circuit components 120. For instance, in some embodiments, a circuit component 120 of a circuit of the electronic device 100 includes a terminal, an energy source (e.g., a power supply), an interconnect (e.g., a line interconnect, such as a wire), a load (e.g., a device such as a display, a sensor, etc.), a controller (e.g., switch, CPU 174 of FIG. 1), or a combination thereof. As a non-limiting example, in some embodiments, the circuit components 120 includes a terminal, resistor, transistor, capacitor, inductor, transformer, diode, sensor, or combination thereof. In some embodiments, a first circuit component 122-1 is the same type of component as a second circuit component 122-2 (e.g., both the first circuit component 122-1 and the second circuit component 122-2 include a load or a conductor, etc.). However, the present disclosure is not limited thereto.

In some embodiments, the first circuit component 122-1 and the second circuit component 122-2 form part of an active-matrix array. For instance, in some embodiments, the first circuit component 122-1 or the second circuit component 122-2 is a transistor, electrode, or capacitor disposed on a deformable substrate 110 of the electronic device 100, and the other of the first circuit component 122-1 or the second circuit component 122-2 is different than the transistor, the electrode, or the capacitor of the first circuit component 122-1 or the second circuit component 122-2.

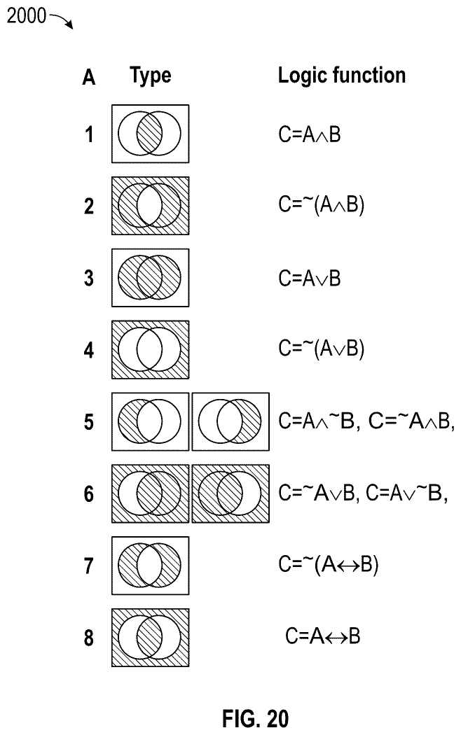

In some embodiments, the first circuit component 122-1 and the second circuit component 122-2 are part of a transistor switch. For instance, in some embodiments, the transistor switch is configured to control an electronical communication through the electronic device 100 using a logic function, such as an OR logic function based on either a cutoff or saturation of the electronic communication. In some embodiments, two or more transistor switches are arranged (e.g., in series and/or parallel) in order to implement a logic function, such as one or more logic functions of FIG. 20.

In some embodiments, the electronic device 100 can include numerous circuit components 120 (e.g., first circuit component 122-1, second circuit component 122-2, . . . , circuit component T 122-T), where T can be up to one million or more. The circuit components 120 are interconnected through traces 124. Accordingly, the electronic device 100 of the present disclosure is capable of incorporating a variety of circuit components, which allows providing electronic devices 100 of high complexity, such as wearable garment electronic devices 100, with deformable substrates 110 that permit continuous electronic communication between two or more circuit components 120 of the electronic device 100 when the electronic device 100 is physically deformed.

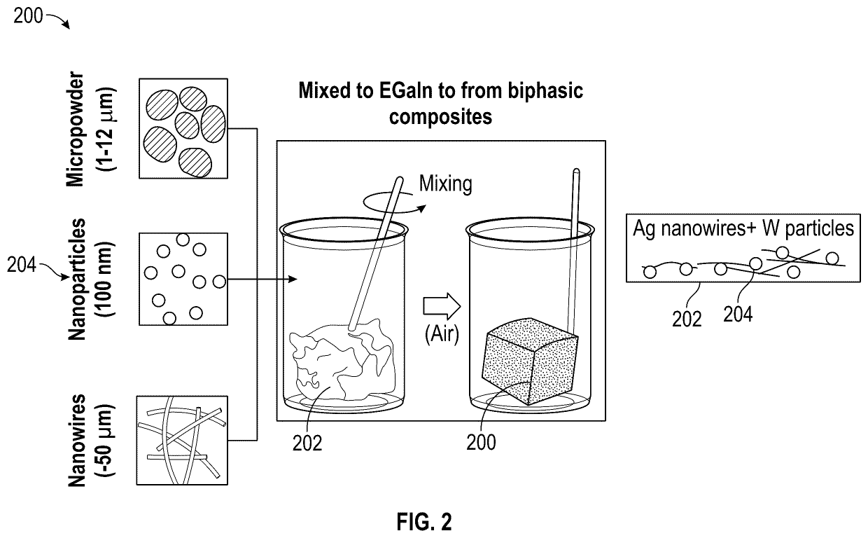

FIG. 2 illustrates a process for forming a composition 200 in accordance with some embodiments of the present disclosure. The composition 200 is used to form traces 124 of FIG. 1. The composition 200 is formed by mixing nanoparticles (e.g., 100 nm particles) of a barrier material 204 (e.g., silver) plus tungsten (W) micro-powder (e.g., 1-12 μm) in a nanowires liquid Ga-based alloy 202.

In some embodiments, the liquid Ga-based alloy includes a gallium indium alloy (e.g., EGaIn), a gallium tin alloy, a gallium indium tin alloy (e.g., Galinstan), a gallium indium tin zinc alloy, or any combination thereof. In some embodiments, the gallium in the liquid Ga-based alloy is between about 25 and 95 percent by weight of the liquid Ga-based metal alloy. In some embodiments, the Ga-based liquid metal alloy includes Ga75.5In24.5, Ga67In20.5Sn12.5, Ga61In25Sn13Zn1, or any combination thereof. Ga75.5In24.5 has a melting point of about 15.5° C., Ga67In20.5Sn12.5 has a melting point of about 10.5° C., and Ga61 In25Sn13Zn1 has a melting point of about 7.6° C.

The term “liquid metal” or “LM” generally refers to any metal or metal alloy that has a relatively low melting temperature under normal pressure and atmospheric conditions. For instance, a liquid metal can have a relatively low melting temperature that is at or below about 100° C., at or below about 80° C., at or below about 60° C., at or below about 40° C., at or below about 20° C., at or below about 10° C., at or below about 0° C., at or below about −10° C., at or below about −20° C., or at or below about −30° C. In certain embodiments, a liquid metal is liquid at or near room temperature (e.g., from about 0° C. to about 40° C., or from about 10° C. to about 30° C.) in stressed or unstressed, deformed or undeformed state.

In some embodiments, the liquid Ga-based alloy includes more than one alloy. For instance, in an embodiment, the liquid Ga-based alloy includes both EGaIn and Galinstan. In some embodiments, the liquid Ga-based alloy includes one or more other additional, optional or alternative substances. For instance, in an embodiment, the liquid Ga-based alloy includes a metal alloy made of copper along with one or more of gallium, indium, and/or tin. In some embodiments, the liquid metal includes a nickel-titanium alloy (nitinoal).

As used herein, the term “alloy” refers to a mixture of two or more substances, with at least one substance being metal. For instance, an alloy can be a mixture of two or more metals, or a mixture of one or more metals and one or more non-metals. In certain embodiments, an alloy is a eutectic mixture, i.e., a mixture of two or more substances at specific proportions such that the mixture changes phase to liquid at a eutectic point relatively lower than a melting point of the pure substances. For instance, in some embodiments, EGaIn is composed of 75.5% Ga and 24.5% In by weight. In some embodiments, EGaIn changes phase to liquid at about 15.7° C., which is lower than the gallium's melting point of about 29.8° C. and the indium's melting point of about 156.6° C.

In some embodiments, the metal filler is at an amount of between 0.2 wt % to 4 wt % with respect to the liquid Ga-based alloy. For instance, in some embodiments, the metal filler is at an amount within a range of about 0.2 wt % to 4 wt % with respect to the liquid Ga-based alloy. In some embodiments, the metal filler is aluminum, silver, an alloy thereof, or a combination thereof. In some embodiments, the metal filler is aluminum or an alloy thereof.

In some embodiments, the metal filler is silver or an alloy thereof. Moreover, the metal filler is at an amount of between 1 wt % to 2 wt % with respect to the liquid Ga-based alloy. In some embodiments, the miscibility of the metal filler and the liquid Ga-based alloy is characterized by a negative Gibbs free energy binding value. For instance, in some embodiments, the miscibility of the metal filler and the liquid Ga-based alloy is characterized by a first Gibbs free energy binding value associated with the metal filler that is less than a second Gibbs free energy binding value associated with the liquid Ga-based alloy. In some embodiments, the second Gibbs free energy binding value is within a range of 960 kilojoules per mol (kJ mol-1) to 1050 KJ mol-1.

One aspect of the present disclosure provides an optimized liquid metal that has beneficial corrosion resistance properties. For instance, in some embodiments, a trace in a plurality of traces embedded in a stretchable or flexible substrate of an electronic device includes a formulation. In some embodiments, the formulation is water-resistant by adding a low water-permeable elastomer and making an LM-composite ink. In some embodiments, the formulation includes a binder that is a thermoplastic elastomer, such as styrene isoprene styrene (SIS) and silver, but results in high electrical resistivity in comparison to pure EGaIn. Moreover, in some embodiments, the formulation has excellent wettability and stretchability over a variety of substrate surfaces. In some embodiments, the formulation achieved a conductivity similar to pure EGaIn with the viscosity that is suitable for vacuum filling. In some embodiments, the formulation includes 2 wt. % silver and 0.4 wt. % SIS. In some embodiments, having electricity conducted through the trace, the formulation showed no signs of oxidation. In some embodiments, the formulation includes a metal with more negative Gibbs free energy than Gallium oxide, which has a Gibbs free energy (ΔGf) of about 1010 kJ per mol, in order to facilitate water reaction with a second filler of the oxidation before oxidation of Ga. In some embodiments, the metal includes aluminum that is characterized by a Gibbs free energy of about −1570 kJ mol-1, since aluminum has a higher propensity to form water-induced oxide than gallium. In some embodiments, the formulation includes the metal as a filler in an amount 0.4 wt. % of aluminum in EGaIn. In some embodiments, the formulation includes the Al filler and the SIS.

In some embodiments, the formulation includes a liquid Ga-based alloy and a metal filler. Furthermore, the metal filler is at an amount of between 0.2 wt % to 4 wt % with respect to the liquid Ga-based alloy. Additionally, the metal filler is aluminum, silver, an alloy thereof, or a combination thereof. In some embodiments, the metal filler reduces a corrosivity of the formulation so the formulation is free of oxidation for a period of time. Moreover, the period of time is at least 500 hours. In some embodiments, the period of time is within a range of about 100 and 10000 hours.

In some embodiments, the formulation satisfies a threshold contact angle in order to wet a layer in the plurality of layers. Moreover, the threshold contact angle is between 0° and 115°. In some embodiments, the formulation includes a contact angle of less than 90 degrees (°) when interfacing with the deformable substrate 110. In some embodiments, the formulation is required to have a threshold contact angle in order to wet a surface of the deformable substrate 110. For instance, in some embodiments, when a first contact angle of the composition when interfacing with the deformable substrate 110 is greater than a second contact angle of the composition when interfacing with the deformable substrate 110, the second contact angle is said to have improved wettability in comparison to the first contact angle. In some embodiments, the threshold contact angle is within a range of about 0° to 115°.

In some embodiments, the formulation further includes a binder. In some embodiments, the binder includes a thermoplastic elastomer. For instance, in some embodiments, the binder includes toluene, tetrahydrofuran (THF), cycolohexane, xylene, decane, octyle acelate, or 2,2,4-Trimethyl-1,3-pentanediol disobutyrate (TXIB). Non-limiting examples of the binder include, but are not limited to, thermoplastic polymer, cellulose, polyvinyl alcohol, polyacrylic acid, polyvinylidene fluoride, polyvinyl acetate-polyvinylpyrrolidone, polyethylene glycol, amines, silicones, styrene isoprene styrene (SIS), styrene ethylene butylene styrene (SEBS), or any combination thereof.

In some embodiments, the thermoplastic elastomer is styrene isoprene styrene (SIS), styrene-ethylene-butadiene-styrene (SEBS), styrene-butadiene-styrene (SBS), and poly (styrene-block-isobutylene-block-styrene) (SIBS), a thermoplastic polyurethane (TPU), a thermoplastic copolyester (TPE-E, COPE, etc.), a thermoplastic polyolefins (TPO), a thermoplastic Vulcanizate (TPV), styrene-ethylene/propylene-styrene (SEPS), styrene-ethylene/propylene (SEP), styrene-isoprene (SIR), a mixture thereof.

In some embodiments, the binders includes, but are not limited to, thermoplastic polymer, cellulose, polyvinyl alcohol, polyacrylic acid, polyvinylidene fluoride, polyvinyl acetate-polyvinylpyrrolidone, polyethylene glycol, amines, silicones, styrene isoprene styrene (SIS), styrene ethylene butylene styrene (SEBS), or any combination thereof.

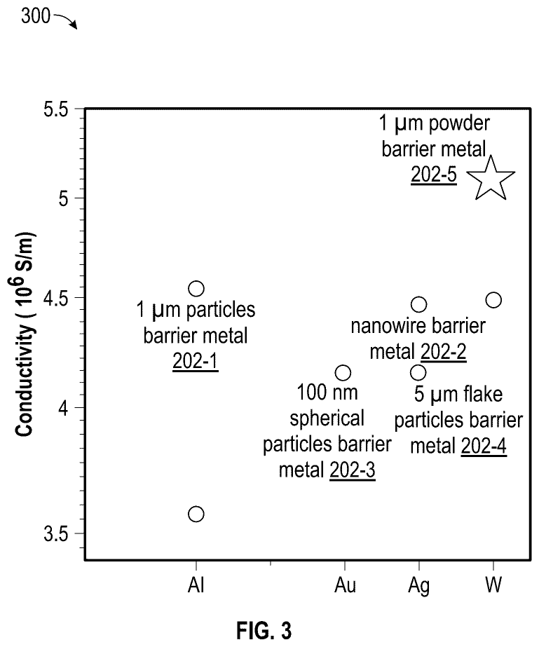

FIG. 3 is a chart 300 illustrating conductivity of a variety of compositions with various barrier metals in accordance with some embodiments of the present disclosure. The conductivity in chart 300 is provided in units of 106 S/m. The variety of compositions include aluminum (Al) in the form of 1 mm particle barrier metal (202-1), gold (Au)) in the form of 110 nm spherical particles of barrier metal (202-3), silver (Ag) in the form of nanowire barrier metal (202-2) and 5 c flake particle barrier metal (202-4), and W in the form of 1 mm barrier metal (202-5).

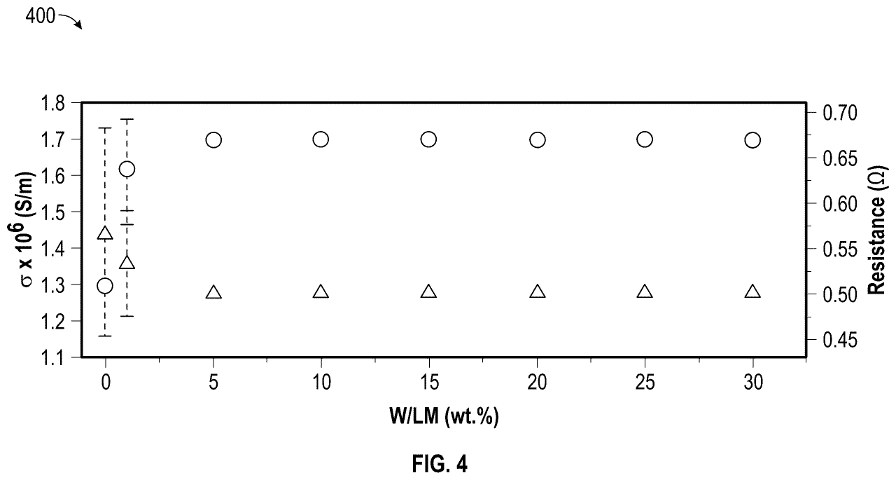

FIG. 4 is a chart 400 illustrating a conductivity and a resistance of a composition with varying weight percent (wt %) of a barrier metal with a liquid Ga-based alloy, in accordance with some embodiments of the present disclosure. The data in chart 400 indicate that the conductivity and resistivity of the composition is not sensitive to the variation of weight percent of the barrier metal within the liquid Ga-based alloy for the percentage range of about 5 to 30 percent.

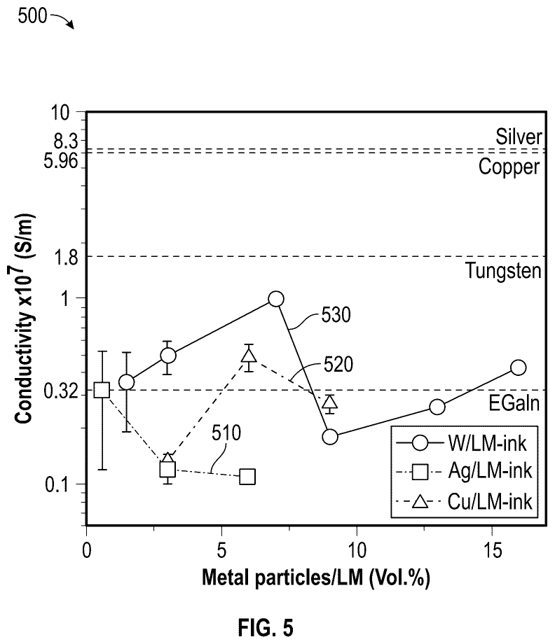

FIGS. 5, 6, 7, 8, 9, 10, 11, and 12 illustrate charts of a conductivity of a composition with varying volume percent (% Vol) of a barrier metal with a liquid Ga-based alloy, in accordance with some embodiments of the present disclosure.

The chart 500 of FIG. 5 includes plots 510, 520 and 530, respectively, corresponding to copper (Cu), Ag and W barrier metals in the composition.

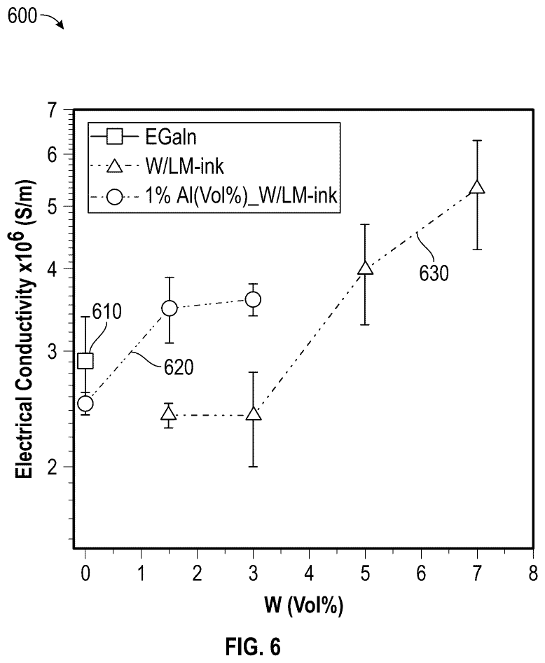

The chart 600 of FIG. 6 includes plots 610, 620 and 630, respectively, corresponding to W, eutectic gallium indium mixture (EGaIn), and 1% Al (Vol %) plus W used as barrier metals in the composition.

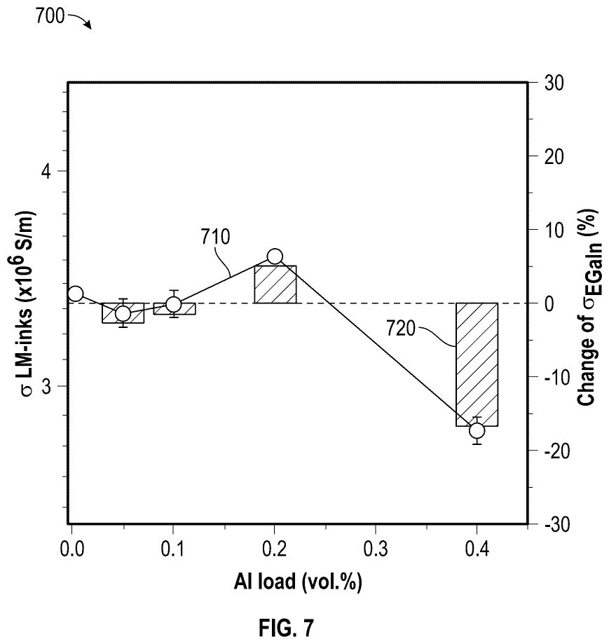

The chart 700 of FIG. 7 includes plots 710 and 720, respectively, corresponding to conductivity of LM-ink (in 106 S/m) and change of conductivity of EGaIn (in %) with Al load Vol % less than 0.5 percent.

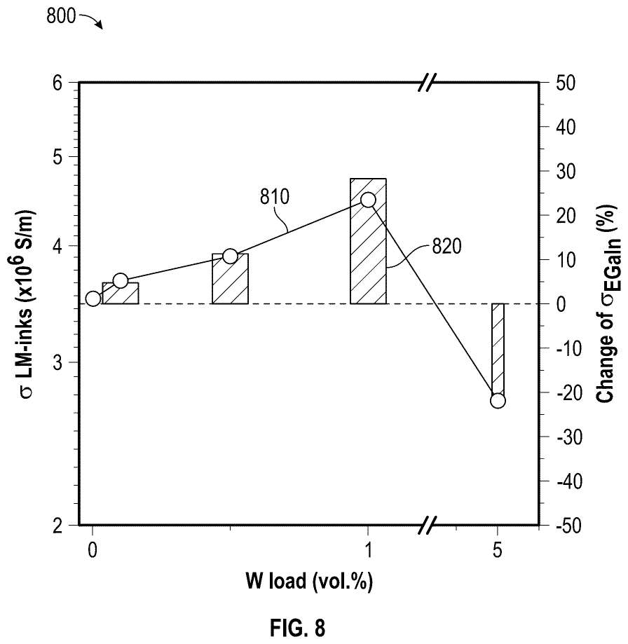

The chart 800 of FIG. 8 includes plots 810 and 820, respectively, corresponding to conductivity of LM-ink (in 106 S/m) and change of conductivity of EGaIn (in %) with W load Vol % less than 5 percent.

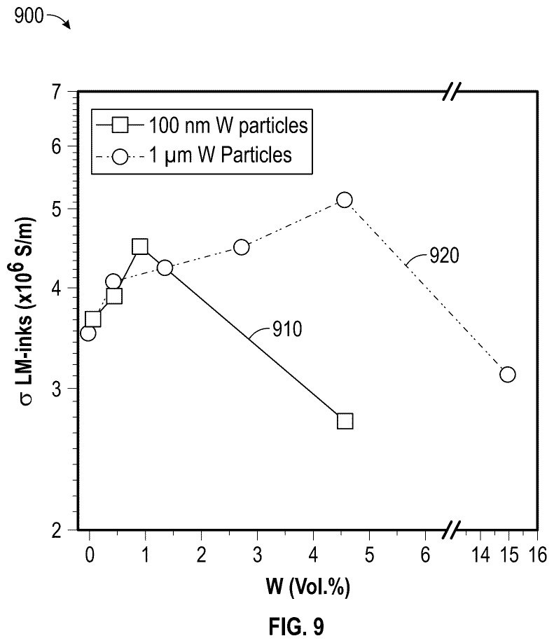

The chart 900 of FIG. 9 includes plots 910 and 920 corresponding to conductivity of LM-ink (in 106 S/m) with W load Vol % less than about 15 percent for 100 nm and 1 mm W particles, respectively.

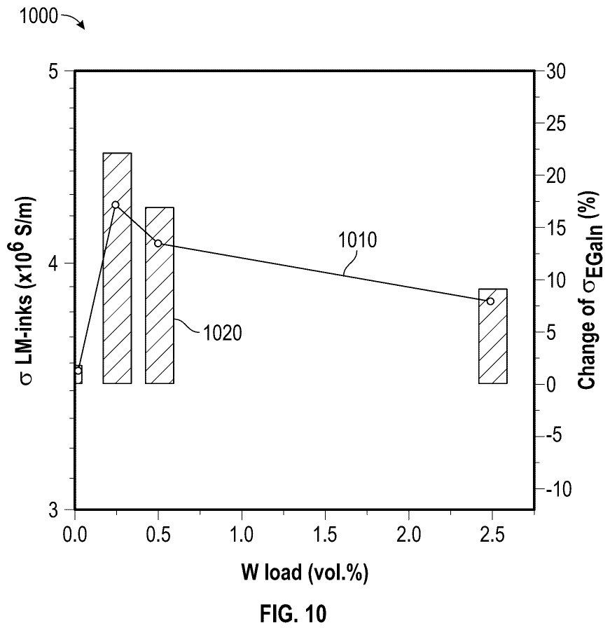

The chart 1000 of FIG. 10 includes plots 1010 and 1020 corresponding to conductivity of LM-ink (in 106 S/m) and change of conductivity of EGaIn (in %) with W load less than about 2.5 percent.

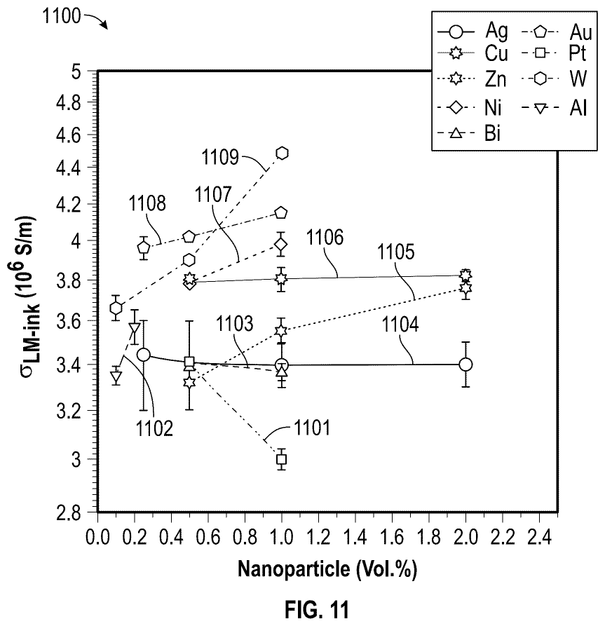

The chart 1100 of FIG. 11 includes plots 1101-1109 corresponding to conductivity of LM-ink (in 106 S/m) with nanoparticle Vol % less than about 2.4 percent for different conductive materials, respectively. Plots 1101, 1102, 1103, 1104, 1105, 1106, 1107, 1108 and 1109, respectively, correspond to bismuth (Bi), nickel (Ni), platinum (Pt), silver (Ag), zinc (Zn), Cu, Al, Au, and W.

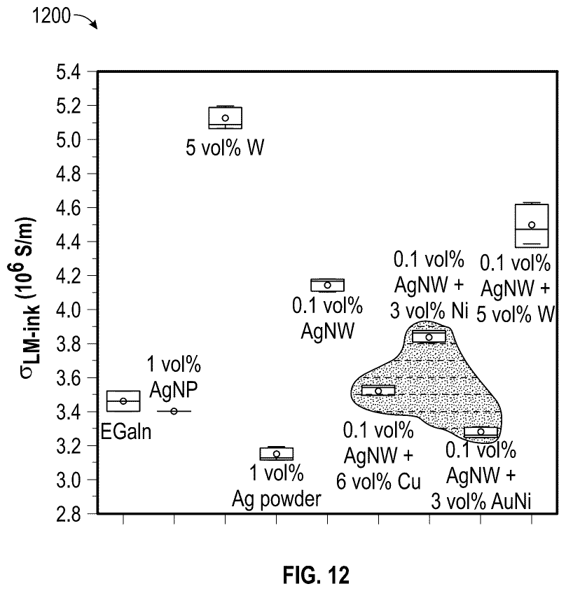

The chart 1200 of FIG. 12 includes plots corresponding to conductivity of LM-ink (in 10⁶ S/m) for a variety of materials with different nanoparticle Vol %., indicating that 5 Vol % of W has the highest conductivity.

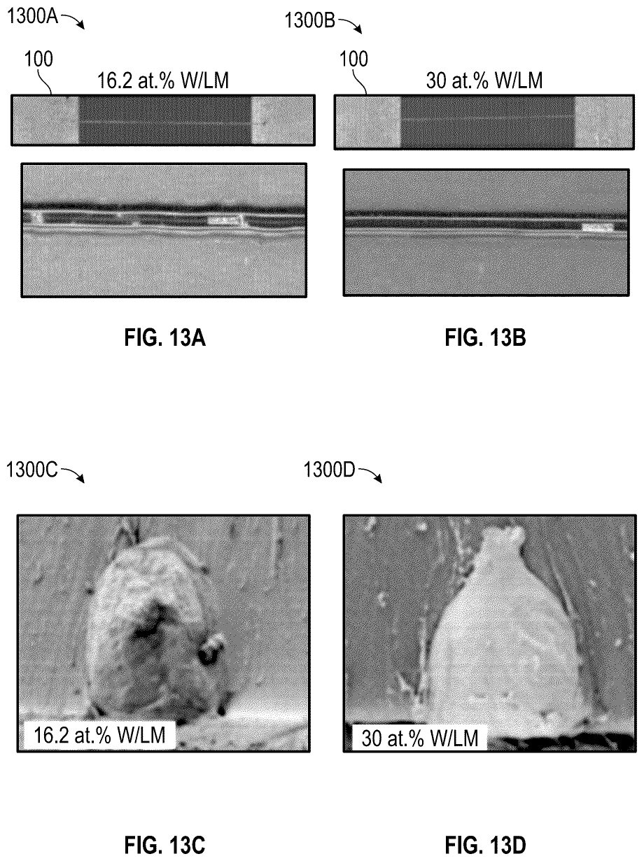

FIGS. 13A, 13B, 13 C and 13D illustrate cross-sectional views of structures 1300A and 1300B of electronic devices and corresponding traces 1300C and 1300D in accordance with some embodiments of the present disclosure. The structure 1300A corresponds to the electronic device 100 of FIG. 1 manufactured using 16.2 Vol % of W as the LM, whereas the structure 1300B corresponds to the electronic device 100 manufactured with 30 Vol % of W as the LM. FIGS. 13C and 13D show traces 1300C and 1300D of the electronic device 100 having the structures the electronic device 100 depicted in FIGS. 13A and 13B.

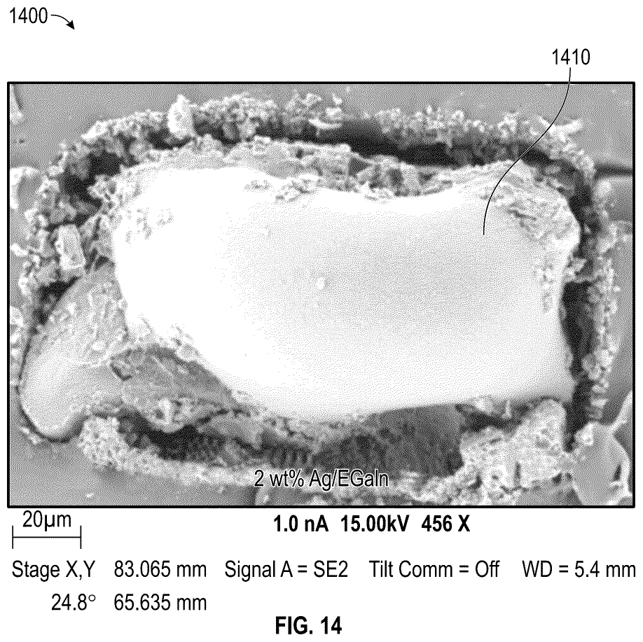

FIG. 14 is a cross-sectional view 1400 of a trace 1410 embedded in a stretchable or flexible substrate of an electronic device, in accordance with some embodiments of the present disclosure. The trace 1410 corresponds to 2 weight (Wt) % Ag/EGaIn liquid metal.

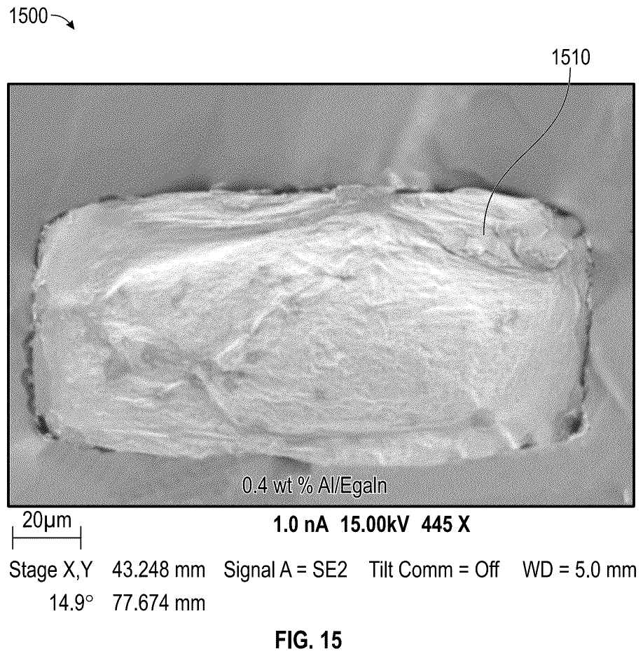

FIG. 15 is a cross-sectional view 1500 of a trace 1510 embedded in a stretchable or flexible substrate of an electronic device, in accordance with some embodiments of the present disclosure. The trace 1510 corresponds to 0.4 weight (Wt) % Ag/EGaIn liquid metal.

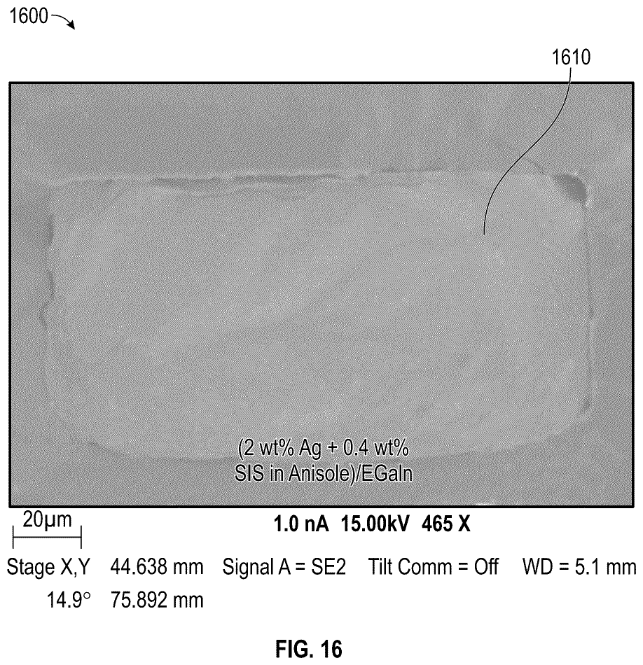

FIG. 16 is a cross-sectional view 1600 of a trace 1610 embedded in a stretchable or flexible substrate of an electronic device, in accordance with some embodiments of the present disclosure. The trace 1610 corresponds to (2 wt % Ag plus 0.4 Wt % sequential infiltration synthesis (SIS) in Anisole)/EGaIn liquid metal.

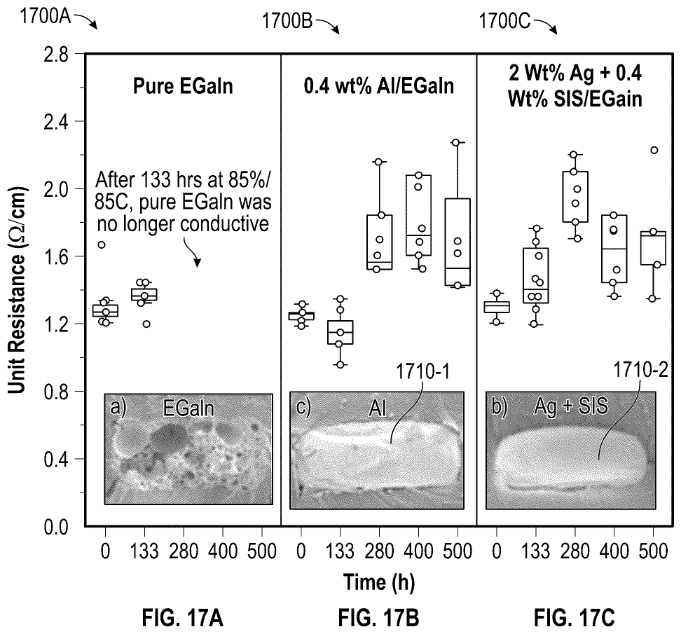

FIGS. 17A, 17B, 17C illustrate charts 1700A, 1700B and 1700C depicting resistance of traces embedded in a stretchable or flexible substrate of an electronic device. The chart 1700A corresponds to a conventional trace of EGaIn. The Charts 1700B and 1700C correspond to two samples of the present disclosure. The chart 1700B shows resistance ((2/cm) versus time (h) for a 0.4 wt % Al/EGaIn liquid metal trace 1710-1 of the subject technology. The chart 1700C shows resistance ((2/cm) versus time (h) for a 2 wt % Ag plus 0.4 Wt % SIS/EGaIn liquid metal trace 1710-2 of the subject technology. The results shown in charts 1700C and 1700C clearly indicate superiority of the traces of the subject technology compared to the conventional trace of EGaIn.

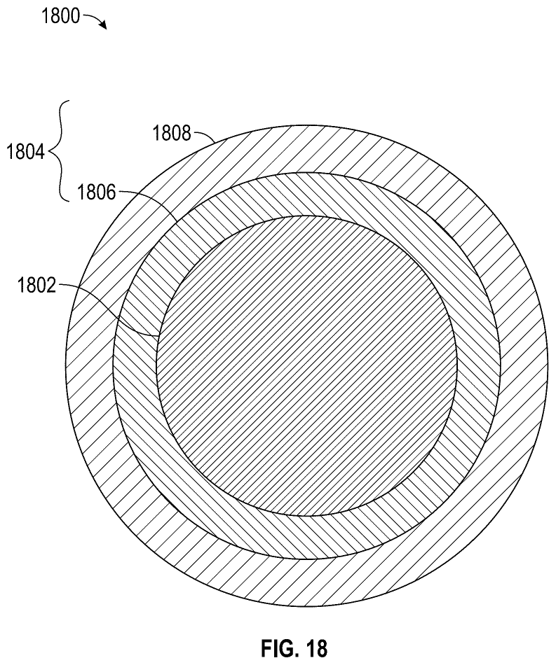

FIG. 18 is a cross-sectional view of a core-shell particle 1800 of a composition, in accordance with some embodiments of the present disclosure. In some embodiments, the core-shell particle includes a core 1802 and one or more layers 1804. For instance, in some embodiments, the layers 1804 include an interior layer 1806 and/or an exterior layer 1808. In some embodiments, the layers 1804 includes the interior layer 1806, the exterior layer 1808, and one or more intermediate layers (not shown for simplicity).

In some embodiments, the core 1802 and the one or more layers 1804 each respectively include a metal material. For instance, in some embodiments, the core 1802 includes a first metal material, the interior layer 1806 includes a second metal material, and the exterior layer 1806 includes a third metal material. In some embodiments, the first metal material is different from the second and third metal materials. In some embodiments, the second metal material is different from the first and third metal materials. In some embodiments, the third metal material is different from the first and second metal materials. In some embodiments, the core 1802, the interior layer 1804, and the exterior layer 1806 each respectively include aluminum, bismuth, gold, hafnium, titanium silver, or tungsten, an alloy thereof, or a combination thereof.

In some embodiments, the liquid Ga-based alloy 202 of FIG. 2 acts as a solvent of the core-shell particle 1800. For instance, in some embodiments, the composition 200 includes a solution, in which the liquid Ga-based alloy 202 acts as a solvent of the core-shell particle 1800. In some embodiments, the core-shell particle includes the same material as the barrier material 204 of FIG. 2.

In some embodiments, the solvent includes anisole (methoxybenzene), toluene, xylene, 2,2,4-Trimethyl-1,3-pentanediol diisobutyrate (TXIB), or a combination thereof. In some embodiments, the solvent includes, but are not limited to toluene, tetrahydrofuran (THF), cycolohexane, xylene, decane, octyle acelate, or 2,2,4-Trimethyl-1,3-pentanediol diisobutyrate (TXIB).

In some embodiments, the solvent includes styrene isoprene styrene (SIS), an organic resin in order to dissolve in 2,2,4-trimethyl-1,3-pentanediol diisobutyrate (TXIB). In some embodiments, SIS is also soluble in tetrahydrofuran (THF), cycolohexane, xylene, decane, and octyle acelate.

Depending on the use (e.g., for direct ink writing, screen printing, or the like), the at least one solvent can have different amounts of the first solvent. For instance, in some embodiments, the at least one solvent includes the first solvent at about 100% by volume, e.g., the at least one solvent consisting of essentially a single solvent (the first solvent) except one or more optional additives, such as a small amount of surfactant for altering the surface tension of the formulation.

In some embodiments, the solvent is a solvent mixture including the first solvent and one, two, three, four, or more than four additional solvents. In some embodiments, the solvent is a solvent mixture including the first solvent of chemical formula I and one, two, three, four, or more than four additional solvents. In some embodiments, the at least one solvent is a solvent mixture including the first solvent of chemical formula II and one, two, three, four, or more than four additional solvents.

The solvent mixture can be tuned, e.g., having each solvent at a specific concentration, to achieve certain properties and/or to suit particular applications. For instance, the solvent mixture can be tuned for the needs of different printing techniques. In some embodiments, the at least one solvent includes the first solvent of chemical formula I or II at an amount from about 3% to about 5%, from about 5% to 10%, from about 10% to 20%, from about 30% to 40%, from about 40% to 50%, or more than 50% by volume of the solvent mixture. In certain embodiments, the first solvent is TXIB and the second solvent is toluene. In an embodiment, TXIB is at an amount from about 2% to about 5%, from about 5% to 10%, or from about 10% to 20% by volume of the solvent mixture.

In some embodiments, the at least one solvent includes a first solvent having chemical formula I or II at an amount from about 3% to about 5%, from about 5% to 10%, from about 10% to 20%, from about 30% to 40%, from about 40% to 50%, or more than 50% by volume of the solvent mixture, and a second solvent at an amount from about 3% to about 5%, from about 5% to 10%, from about 10% to 20%, or from about 30% to 40%, by volume of the solvent mixture, where the second solvent is one of tetrahydrofuran (THF), cyclohexane, xylene, hexanes, decane, or octyle acelate.

In some embodiments, the at least one solvent includes (i) a first solvent having chemical formula I or II at an amount from about 3% to about 5%, from about 5% to 10%, from about 10% to 20%, or from about 30% to 40%, by volume, (ii) a second solvent at an amount from about 3% to about 5%, from about 5% to 10%, or from about 10% to 20%, by volume, and (iii) a third solvent at an amount from about 3% to about 5%, from about 5% to 10%, or from about 10% to 20%, by volume where the second solvent and the third solvent are each independently one of tetrahydrofuran (THF), cycolohexane, xylene, hexanes, decane, or octyle acelate.

In certain embodiments, the at least one solvent includes TXIB, toluene, anisole (methoxybenzene), or any combination thereof. In some embodiments, the at least one solvent includes TXIB and anisole (e.g., TXIB as the first solvent and anisole as the second solvent). In some embodiments, the at least one solvent includes toluene, with or without other solvents. In some embodiments, the toluene is at an amount from about 2% to about 5%, from about 5% to 10%, from about 10% to 20%, from about 20% to 30%, or from about 30% to 40% by volume of the solvent mixture. In some embodiments, the at least one solvent includes anisole, with or without other solvents. In some embodiments, the anisole is at an amount from about 2% to about 5%, from about 5% to 10%, from about 10% to 20%, from about 20% to 30%, or from about 30% to 40% by volume of the solvent mixture.

In some embodiments, the formulation includes a solution of the disclosed solvent-based liquid metal compositions that can be tailored with appropriate solvent(s) and polymer(s) to achieve desired properties, such as improved resistance to oxidation, optimal viscosity, or the like. For instance, in some embodiments, the solution is composed of any one or more polymers (e.g., SIS, SEBS, silicone, or the like) dissolved in TXIB, or in a solvent mixture including TXIB. Non-limiting examples of such embodiments include, but are not limited to, a solution of SIS dissolved in TXIB, a solution of SIS dissolved in a mixture of TXIB and toluene, or a solution of a polymer mixture including SIS dissolved in TXIB. In some embodiments, the solution is composed of SEBS or a polymer mixture including SEBS dissolved in any solvent or solvent mixture. Non-limiting examples of such embodiments include, but are not limited to, a solution of SEBS dissolved in toluene, a solution of a polymer mixture including SEBS dissolved in toluene, or a solution of SEBS dissolved in a mixture of TXIB and toluene.

A solution of the present disclosure can include the at least one solvent and the polymeric binder at any suitable weight ratios. For instance, in some embodiments, a solution of the present disclosure includes the polymeric binder at an amount from about 5% to about 10% by weight, from about 10% to about 20% by weight, or from about 20% to about 30% by weight of the solution.

In some embodiments, the core 1802 is aluminum, bismuth, gold, hafnium, silver, titanium, or tungsten, an alloy thereof, or a combination thereof. In some embodiments, the core 1802 is aluminum, bismuth, copper, gold, hafnium, nickel, silver, titanium, tungsten, an alloy thereof, or a combination thereof. In some embodiments, the core 1802 includes a metal or a metal alloy with a conductivity greater than at least 3.4×10⁶ S/m, which allows for improving the conductivity of the composition 200. As a non-limiting example, in some embodiments, the core 1802 includes tungsten and/or silver. For instance, in some embodiments, the core 1802 is configured to prevent oxidation of the liquid Ga-based alloy.

In some embodiments, the interior layer 1806 is aluminum, bismuth, gold, hafnium, silver, titanium, or tungsten, an alloy thereof, or a combination thereof. In some embodiments, the interior layer 1806 is aluminum, bismuth, copper, gold, hafnium, nickel, silver, titanium, tungsten, an alloy thereof, or a combination thereof. In some embodiments, the interior layer 1806 includes a metal or a metal alloy that does not react or alloy with the liquid Ga-based alloy (e.g., has a smaller Gibbs free energy value, etc.).

In some embodiments, the exterior layer 1808 is aluminum, bismuth, gold, hafnium, silver, titanium, or tungsten, an alloy thereof, or a combination thereof. In some embodiments, the exterior layer 1808 is aluminum, bismuth, copper, gold, hafnium, nickel, silver, titanium, tungsten, an alloy thereof, or a combination thereof. In some embodiments, the exterior layer 1808 includes a metal or a metal alloy that is miscible with the liquid Ga-based alloy (e.g., has a larger Gibbs free energy value, etc.).

In some embodiments, the liquid Ga-based alloy 202 is present in the composition 200 with between 0.5% volume/volume (v/v) and 15.0% v/v of the core-shell particle 1800. For instance, in some embodiments, the liquid Ga-based alloy 202 is present in the composition 200 with between 0.5 and 15.0% v/v, of the core-shell particle 1800. Accordingly, in some embodiments, the % v/v of the liquid Ga-based alloy 202 allows for improved miscibility between the core-shell particle 1800 and the liquid Ga-based alloy 202.

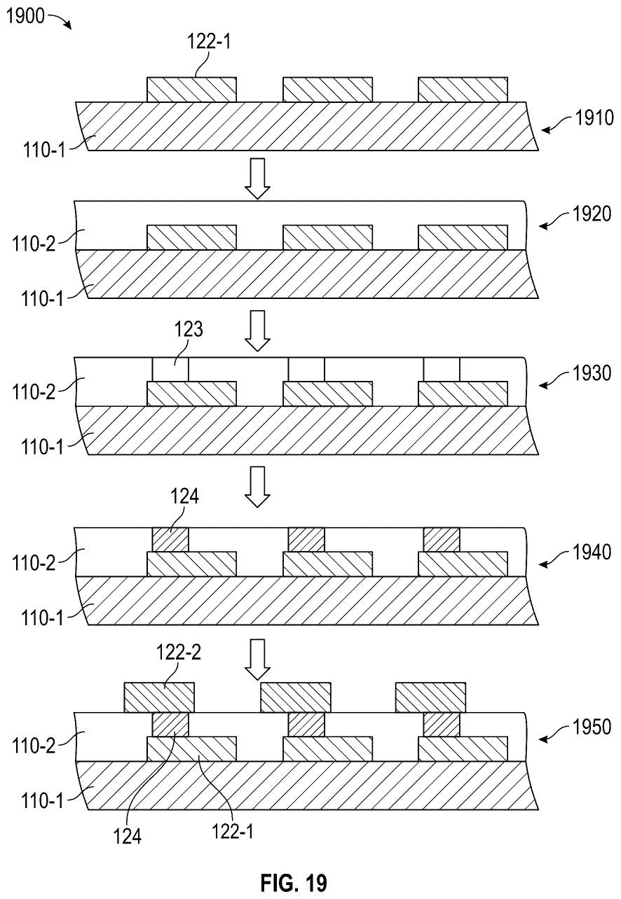

FIG. 19 is a flowchart illustrating method 1900 for manufacturing an electronic device in accordance with some embodiments of the present disclosure. In some aspects, method 1900 depicts a process of manufacturing, for example, the electronic device 100 of FIG. 1, the electronic device 100 of FIG. 13A, electronic device 100 of FIG. 13B, etc.). Method 1900 includes steps 1910, 1920, 1930, 1940 and 1950, as described herein.

In step 1910, a first circuit component 122-1 is formed on first layer 110-1, which is a deformable substrate (e.g., substrate 110 of FIG. 1).

In step 1920, a second layer 110-2 (e.g., a deformable substrate) is formed on the first circuit component 122-1.

In step 1930, using a photolithography process, the second layer 110-2 is suitably etched to form holes 123 for traces 124 to be formed in.

In step 1940, traces 124 are formed in the etched holes 123 in the photoresist 110-2. In step 1950, the second circuit component 122-2 is formed on traces 124.

As used herein, the term “deformable substrate” refers to a substrate or a portion of it (e.g., a layer) capable of altering its shape subject to pressure or stress. For instance, in some embodiments, the deformable substrate or at least a portion of it is flexible, bendable, stretchable, inflatable, or the like. For instance, in some embodiments, the deformable substrate or at least a portion of it (e.g., a layer) is made with a material having a Young's Modulus lower than about 0.5, lower than about 0.4 Gpa, lower than about 0.3 Gpa, or lower than about 0.2 Gpa. Such a material allows the substrate or a portion of it to deform (e.g., bend, stretch or the like) under pressure or strain. In some embodiments, the deformable substrate or at least a portion of it is made of a material having Young's Modulus lower than about 0.1 Gpa to provide enhanced flexibility and tackability. Examples of materials with low Young's Modulus include, but are not limited to elastomeric materials, viscoelastic polymeric materials, synthetic resins having low sliding performance, high corrosion resistance and high strength, such as silicone, medical grade polyurethane, polyethylene terephthalate (PET), polyimide (PI), polyphenylene sulfide (PPS) or fluorine-containing resin.

In some embodiments, the deformable substrate includes a layer or a portion made of a relatively rigid material. For instance, in some embodiments, the deformable substrate includes a layer or a portion made of a material having Young's Modulus higher than about 0.5 Gpa, higher than about 1.0 Gpa, higher than about 2.0 Gpa, higher than about 3.0 Gpa, higher than 4.0 Gpa, or higher than about 5.0 Gpa. Examples of materials with relatively higher Young's Modulus include, but are not limited to, polyethylene, polyetheretherketone (PEEK), polyester, aramid, composite, glass epoxy, and polyethylene naphthalate.

In some embodiments, the deformable substrate includes a supporting material upon or within an object which it is fabricated or attached to or on. In some embodiments, the deformable substrate or a portion of the deformable substrate is processed (e.g., patterned) during manufacture of the object. In some embodiments, the deformable substrate remains substantially unchanged when the object is formed upon or within the deformable substrate. In some embodiments, the deformable substrate includes a planar surface, a substantially planar surface, a curved surface, a round surface (e.g., an edge having a radius of curvature greater than zero), one or more sharp edges, or any combination thereof.

In some embodiments, the deformable substrate is a monolayer substrate consisting of a single layer. In some embodiments, the deformable substrate includes two, three, four, five, or more than five layers. In some embodiments, the deformable substrate includes one or more layers that are removable, e.g., functioning as a sacrificial layer that can be at least partially removed when desired or needed.

In some embodiments, a first circuit component 122-1 of the electronic device 100 includes a terminal, an energy source, an interconnect (e.g., a line interconnect, such as a wire), a load (e.g., a device such as display, a sensor, etc.), a controller (e.g., switch), or a combination thereof. As a non-limiting example, in some embodiments, the circuit component 120 includes a terminal, resistor, transistor, capacitor, inductor, transformer, diode, sensor, or combination thereof. In some embodiments, the first circuit component 122-1 is the same type of component as the second circuit component 122-2. For example, both the first circuit component 122-1 and the second circuit component 122-2 include a load, both the first circuit component 122-1 and the second circuit component 122-2 include a conductor, etc. However, the present disclosure is not limited thereto.

In some embodiments, the first circuit component 122-1 and the second circuit component 122-2 form part of an active-matrix array. For instance, in some embodiments, the first circuit component 122-1 or the second circuit component 122-2 is a transistor, electrode, or capacitor disposed on deformable substrate 110 (e.g., first layer 110-1 and second layer 110-2) of the electronic device 100, and the other of the first circuit component 122-1 or the second circuit component 122-2 is different than the transistor, the electrode, or the capacitor of the first circuit component 122-1 or the second circuit component 122-2.

In some embodiments, the first circuit component 122-1 and the second circuit component 122-2 are part of a transistor switch. For instance, in some embodiments, the transistor switch is configured to control an electronic communication through the electronic device 100 using a logic function, such as an OR logic function based on either a cutoff or saturation of the electronic communication. In some embodiments, two or more transistor switches are arranged (e.g., in series and/or parallel) in order to implement a logic function, such as one or more logic functions of FIG. 20 described below. In some embodiments, the electronic device 100 includes between 2 and 10 million circuit components 120 (e.g., first circuit component 122-1, second circuit component 122-2, . . . , circuit component T 122-T).

Accordingly, the electronic device 100 of the present disclosure is capable of incorporating a variety of circuit components 120, which allows providing electronic devices 100 of high complexity, such as wearable garment electronic devices 100, with deformable substrates 110 that permit continuous electronic communication between two or more circuit components 120 of the electronic device 100 when the electronic device 100 is physically deformed.

In some embodiments, traces 124 are vias that couple the first circuit component 122-1 and second circuit component 122-2 and are made of a composition 200 of the present disclosure. In some embodiments, the composition 200 is formed by mixing nanoparticles (e.g., 100 nm particles) of a barrier material 204 of FIG. 2 (e.g., silver) plus tungsten (W) micro-powder (e.g., 1-12 mm) in a nanowires liquid Ga-based alloy 202 of FIG. 2. In some embodiments, traces 124 are configured to maintain conductivity with resistance of between 0.1 Ω/cm and 110 Ω/cm when the deformable substrate (e.g., first layer 110-1 and second layer 110-2) is subjected to 100% strain.

FIG. 20 illustrates exemplary logic functions 2000 that can be implemented into an electronic device in accordance with some embodiments of the present disclosure. The logic functions 2000 include: 1) AND; 2) NAND; 3) OR; 4) NOR; 5) Exclusive OR; 6) Exclusive NOR; 7) inequivalence; and 8) equivalence gates.

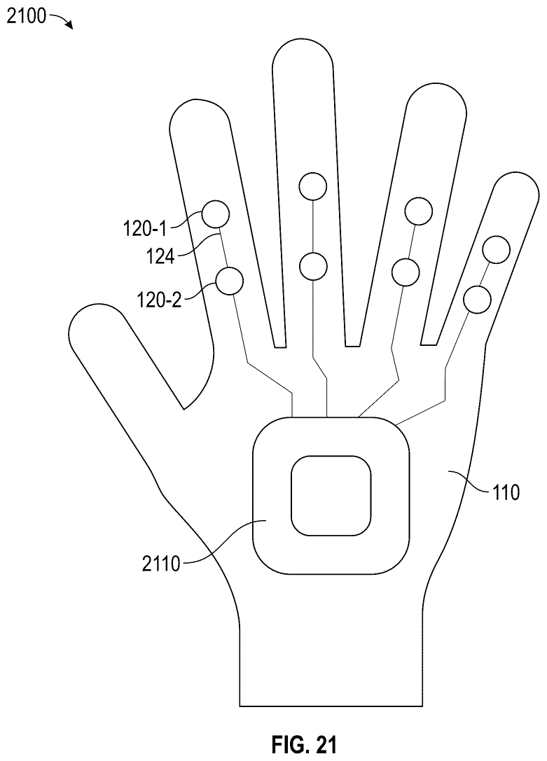

FIG. 21 illustrates an electronic device 2100 in accordance with some embodiments of the present disclosure. In the example shown in FIG. 21, the electronic device is a smart glove made of a deformable substrate 110 as described above. The smart glove also includes first and second circuit components 120-1 and 120-2, as described above., which are in connected with through traces 124. The first and second circuit components 120-1 and 120-2, can among other circuits, include touch sensors, actuators that are in communication and controlled with a controller 2110 (e.g., a microcontroller or processor).

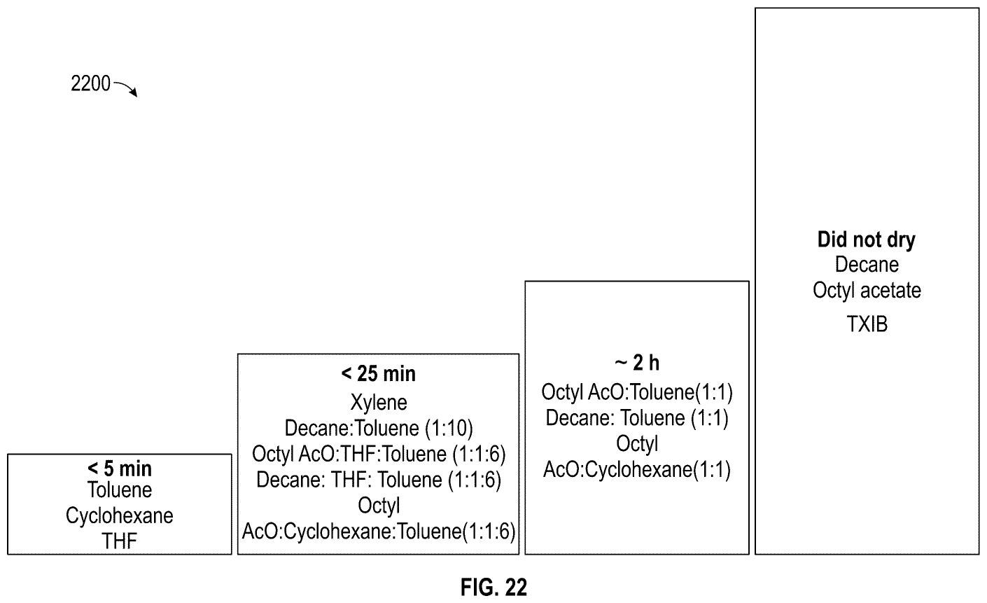

FIG. 22 is a bar chart 2200 illustrating drying times of solution drops on a glass slide at lab temperature, in accordance with some embodiments of the present disclosure. One aspect of the present disclosure provides solvent-based liquid metal compositions. The compositions are used, for instance, in the manufacture of electronic devices as disclosed herein. The compositions generally include a solution having at least one solvent and a polymeric binder dissolved in the solvent. The compositions also include a LM mixed with the solution. In some embodiments, additionally or optionally, the compositions include a metallic filler. The metallic filler can be added prior to, currently with, or subsequent to the LM being mixed with the solution.

Additionally or optionally, the compositions of the present disclosure are tuned to achieve a higher electrical conductivity (e.g., a conductivity measured after the composition is printed, dried or cured). For instance, in some embodiments, a composition of the present disclosure has a measured conductivity, at either the time the composition is used for tracing or after polymerization following tracing, of greater than about 3×10⁵ S/m (siemens per meter), greater than about 4×10⁵ S/m, greater than about 5×10⁵ S/m, greater than about 6×10⁵ S/m, greater than 7×10⁵ S/m, greater than 8×10⁵ S/m, greater than 9×10⁵ S/m, greater than 1×10⁶ S/m, greater than 1.1×10⁶ S/m, or greater than 1.2×10⁶ S/m.

In searching for a solvent or solvent mixture to substitute or combine with toluene, polymer solubility tests have been performed to screen potential solvents. It has been found that styrene isoprene styrene (SIS), an organic resin commonly used in LM inks, can dissolve in 2,2,4-trimethyl-1,3-pentanediol diisobutyrate (TXIB). Specifically, at a room temperature, SIS can dissolve in TXIB at an amount of 15 wt % or more. In addition to TXIB, SIS is also soluble in tetrahydrofuran (THF), cycolohexane, xylene, decane, and octyle acelate. FIG. 1 shows solutions of 15 wt % SIS in various solvents or solvent mixtures. The LM makes the composition electrically conductive once it is printed, dried or cured.

Table I below shows these solvents along with their boiling temperatures and vapor pressures. As can be seen, xylene, decane, octyle acelate and TXIB have higher boiling temperatures and lower vapor pressures than toluene. Accordingly, these solvents are less volatile than toluene, and using them in the formulations will result in longer decap times.

TABLE I
Physical Properties of Some Solvents

| Solvent | Boiling Point (° C.) | Vapor Pressure at 20° C. (mbar) |
|---|---|---|
| THF | 66 | 173 |
| Cyclohexane | 80.7 | 124 |
| Toluene | 110 | 38 |
| Xylene | 138 | 9 |
| Decane | 174 | 1.9 |
| Octyl Acetate | 211 | 0.5 |
| TXIB | 380 | 0.01 (at 25° C.) |

Returning to FIG. 22, the bar chart 2200 shows drying times of various 15 wt % SIS solutions (i.e., the weight of SIS is 15% with respect to the weight of the solvent). The drying test is performed on a glass slide at lab temperature. Drops of 15 wt % SIS in different solvents or solvent mixtures are deposited on a glass slide and dry times are recorded. That is, after adding SIS to the solvent, the SIS makes up fifteen percent by weight of the solvent/solute combination whereas the solvent makes up the remaining 85 wt %. As shown in bar chart 2200, at lab temperature, a drop of 15 wt % SIS in toluene would dry within less than 5 minutes, while a drop of 15 wt % SIS in xylene would dry within less than 25 minutes, and a drop of 15 wt % SIS in decane, octyle acelate or TXIB would not dry for over 2 hours. TXIB is safe to use. It can be found in apparel, weather stripper, furniture, wallpaper, nail care, plastisols, sheet vinyl flooring, toys/sporting goods, traffic cones, vinyl compounding, vinyl gloves, inks, coatings, urethane elastomers, and water-based paints.

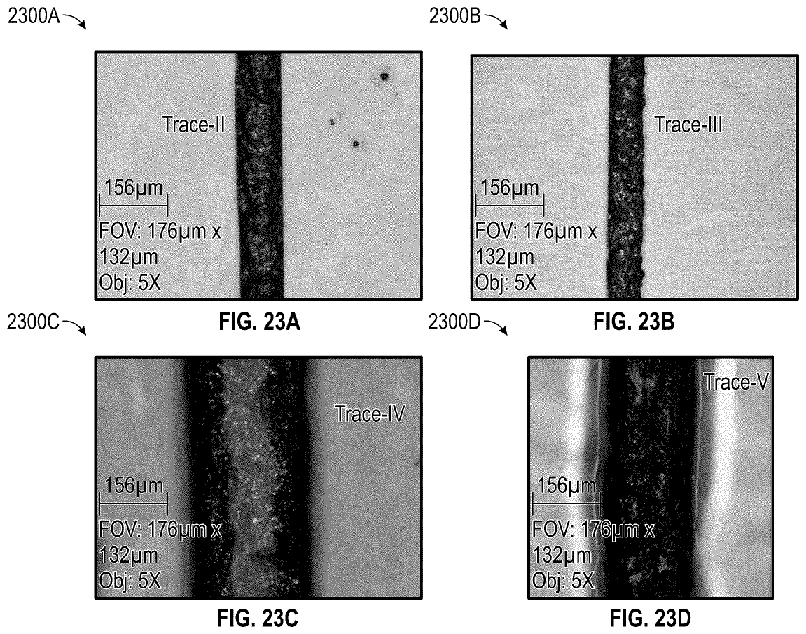

FIGS. 23A, 23B, 23C and 23D are images of traces made of exemplary compositions, in accordance with some embodiments of the present disclosure. To demonstrate the use of the compositions of the present disclosure, traces are made of these exemplary compositions and resistances of the traces are measured under 100% cyclic strain.

Exemplary traces are listed in Table-III below and shown in FIGS. 23A-23D. Specifically, composition-I, composition-II and composition-III are used to print single traces, i.e., trace-I, trace-II and trace-III, respectively. Composition-I and composition-IV are used to print four traces in parallel, i.e., trace-IV and trace-V, respectively. Both single traces and four traces in parallel are printed using stainless steel stencil.

TABLE III
Exemplary Traces Printed Using Stainless Steel Stencil

| | | | Thickness | Width |
|---|---|---|---|---|
| Examples | Compositions | Encapsulation | (μm) | (μm) |
| Trace-I | Composition-I | Encapsulated | 88 | 204 |
| (single) | | with bluesil | | |
| Trace-II | Composition-II | Not encapsulated | 48 | 228 |
| (single) | | | | |
| Trace-III | Composition-III | Not encapsulated | 49 | 204 |
| (single) | | | | |
| Trace-IV | Composition-I | Encapsulated | 200 | 500 |
| (4 traces) | | with bluesil | | |
| Trace-V | Composition-IV | Encapsulated | 200 | 500 |
| (4 traces) | | with bluesil | | |

For comparison reasons, the dimensions of trace-I, trace-II and trace-III are kept more or less the same. Specifically, as shown in Table-III, trace-I (made of composition-I) is encapsulated with bluesil and has a thickness of about 88 μm. Trace-II (made of composition-II) and trace-III (made of composition-III) are not encapsulated and have a thickness of about 48.5 μm±0.5 μm. All of the three traces have a similar width of about 216 μm±12 μm.

Similarly, for comparison reasons, the dimensions of trace-IV and trace-V are kept substantially the same. Specifically, as shown in Table-III, both trace-IV (made of composition-I) and trace-V (made of composition-IV) are encapsulated and have a thickness of about 200 μm and a width of about 500 μm.

Resistances of these traces are measured at 100% cyclic strain and 5 second per cycle. A 5 second cycle under 100% strain refers to a process in which a strain is applied in the first half of 5 seconds (2.5 seconds) to stretch the traces to double their lengths and then the strain is released in the second half of 5 seconds.

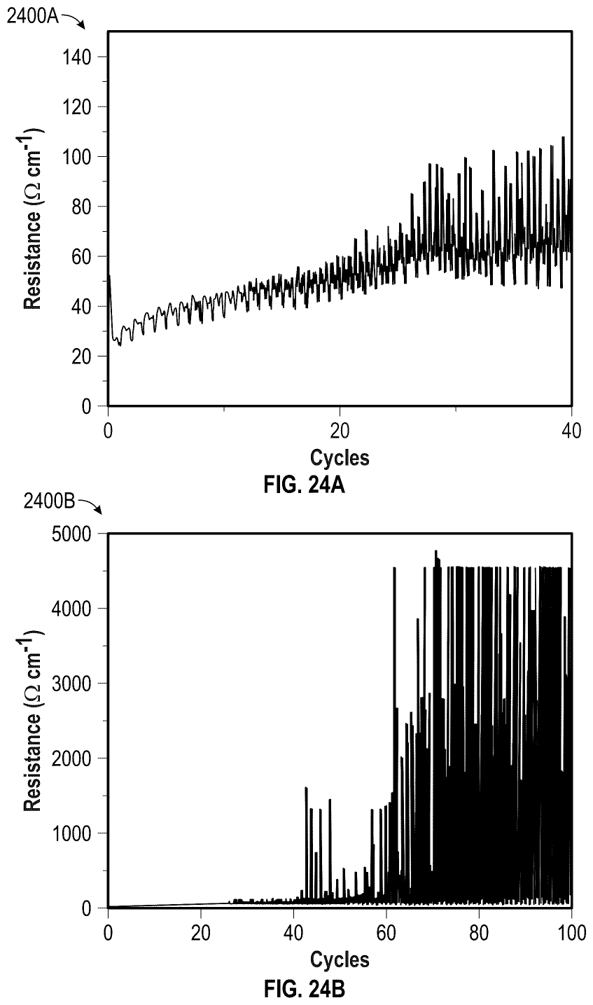

FIGS. 24A and 24B are graphs 2400A and 2400B showing a resistance of a first trace measured at 100% cyclic strain, in accordance with some embodiments of the present disclosure. Graphs 2400A and 2400B show the measured resistance of trace-I made of composition-I (i.e., with SIS dissolved in toluene). As shown, the resistance of trace-I starts to rise after about 40 cycles and reaches 4000 Ω/cm or higher after about 70 cycles. Since the electrical conductivity is inversely proportional to the resistance, this measured resistance indicates a significant decrease in the electrical conductivity of composition-I after about 70 cycles.

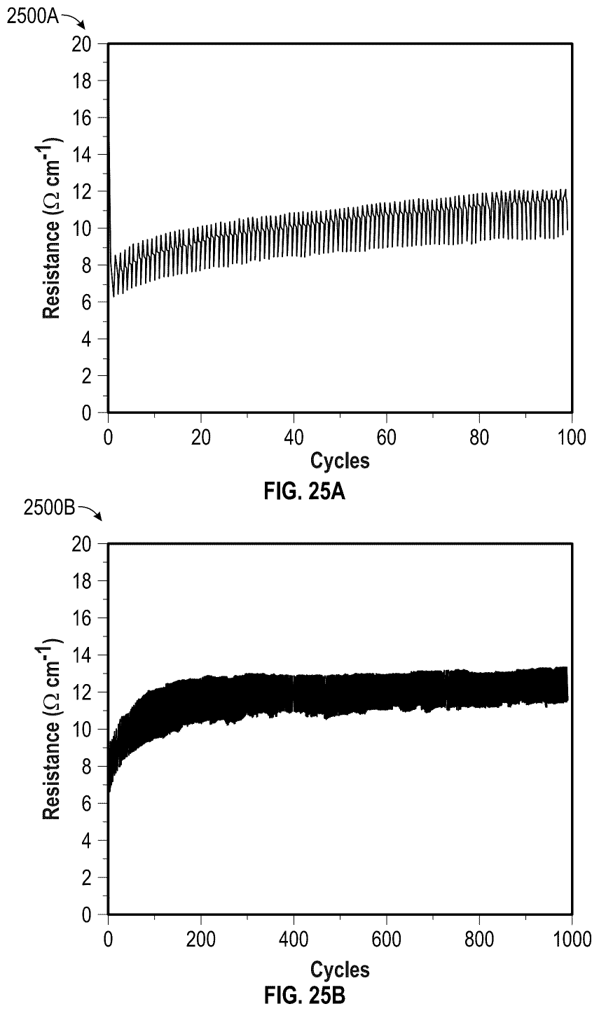

FIGS. 25A, 25B and 25C are graphs 2500A, 2500B and 2500C showing a resistance of a second trace measured at 100% cyclic strain, in accordance with some embodiments of the present disclosure. Graphs 2500A, 2500B and 2500C show the measured resistance of trace-II made of composition-II (i.e., with SIS dissolved in TXIB). As shown, the resistance of trace-II maintains a low resistance of less than 15 Ω/cm for about 2000 cycles, and only then reaches 4000 Ω/cm or higher. This indicates that the electrical conductivity of composition-II remains at a substantially high level for 2000 cycles.

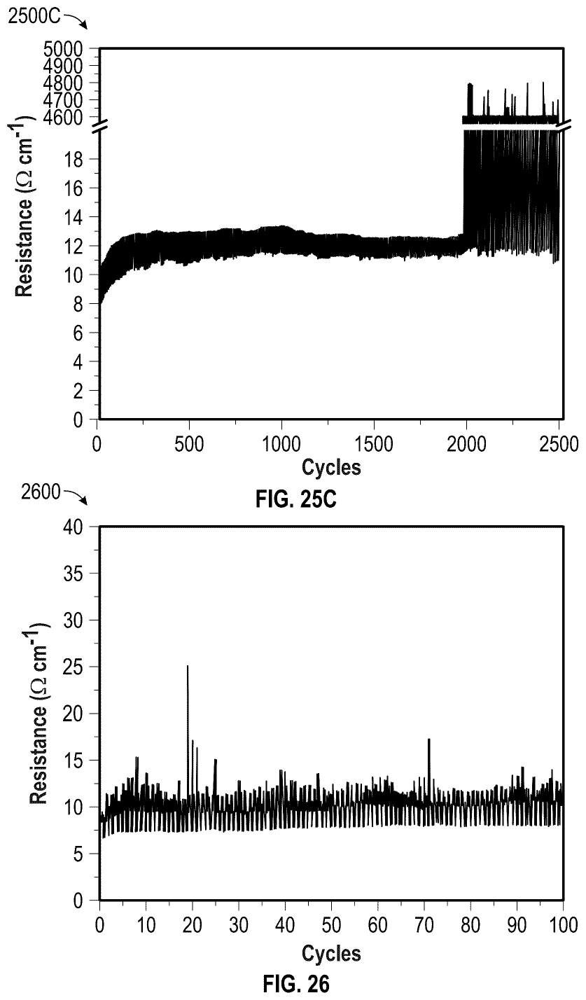

FIG. 26 is graph 2600 showing a resistance of a third trace measured at 100% cyclic strain, in accordance with some embodiments of the present disclosure. Graph 2600 shows the measured resistance of trace-III made of composition-III (i.e., with SIS dissolved in TXIB: toluene 5% v/v). As shown, the resistance of trace-III maintains a low resistance of less than 15 (2/cm for at least 100 cycles. This indicates that the electrical conductivity of composition-II remains at a substantially high level for at least 100 cycles.

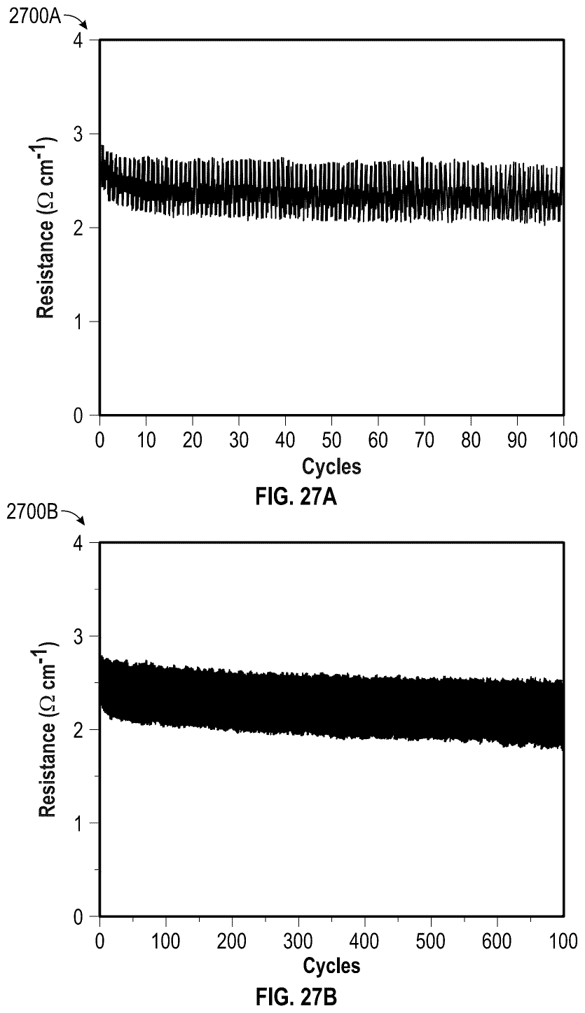

FIGS. 27A and 27B are graphs 2700A and 2700B showing a resistance of a fourth trace measured at 100% cyclic strain, in accordance with some embodiments of the present disclosure. Graphs 2700A and 2700B show the measured resistance of trace-IV made of composition-I (i.e., with SIS dissolved in toluene). As shown, the resistance of trace-IV maintains a low resistance of less than 3 Ω/cm for at least 700 cycles. This indicates that the electrical conductivity of composition-IV remains at a substantially high level for at least 100 cycles.

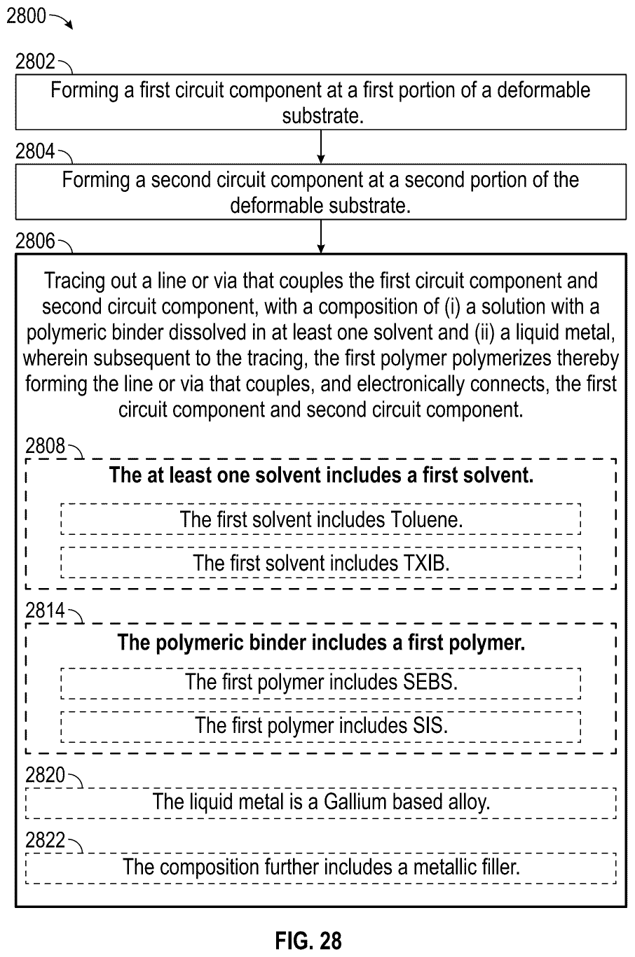

FIG. 28 is a flowchart illustrating a method 2800 for manufacturing an electronic device, in which optional embodiments are indicated by dashed boxes, in accordance with some embodiments of the present disclosure. The method 2800 includes forming a first circuit component at a first portion of a deformable substrate (block 2802) and forming a second circuit component at a second portion of the deformable substrate (block 2804). The method also includes tracing out a line or via that couples the first circuit component and second circuit component, with a composition of (i) a solution with a polymeric binder dissolved in at least one solvent and (ii) a liquid metal (block 2806). Block 2806 also include optional blocks 2808, 2814, 2820 and 2822.

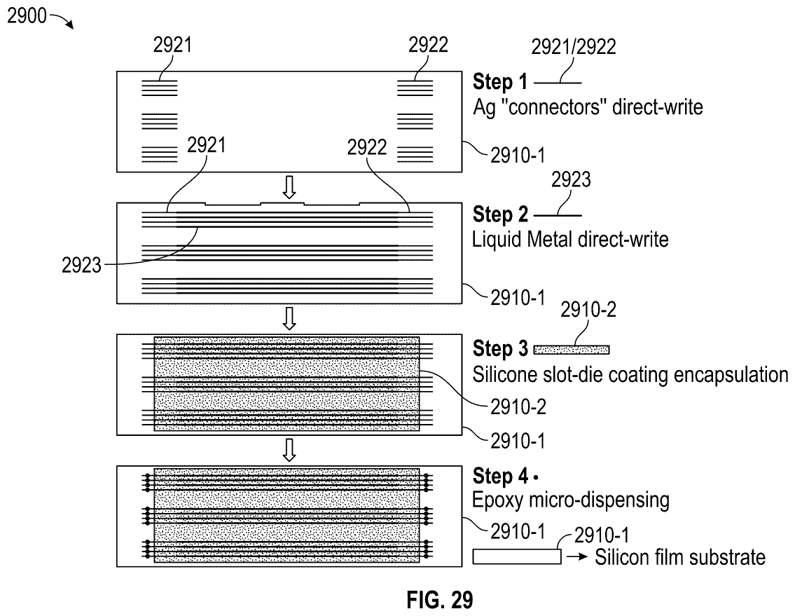

FIG. 29 is a flowchart illustrating a method 2900 for manufacturing an exemplary circuit of an electronic device, in accordance with some embodiments of the present disclosure. In some implementations, to trace out a line that couples the first circuit component and second circuit component the method 2900 forms the first and second circuit components on a common layer of the substrate. For example, the method 2900 forms a first set of first circuit components 2921 and a second set of second circuit components 2922 on a common layer, e.g., a first layer 2910-1, of the deformable substrate 2910. In particular, the first set of first circuit components 2921 is formed on a first portion of the common layer of the deformable substrate 2910, and the second set of second circuit components 2922 is formed on a second portion of the common layer of the deformable substrate 2910. In some embodiments, each of the first and second circuit components is made of a material including Cu, Au, Ag, or a combination thereof. The method then forms a third set of third circuit components 2923, each being a line, to couple the first set of first circuit components and a second set of second circuit components. In some embodiments, a second layer 2910-2 is applied to encapsulate at least a portion of the first layer 2910-1, for instance, using a slot-die coating technique. In some embodiments, the second layer 2910-2 is made of a material including Si.

To form a via that couples the first circuit component and second circuit component, in some embodiments, the method forms the first and second circuit components on two different layers (one layer being a first portion and the other being a second portion) of the deformable substrate 910, as discussed below.

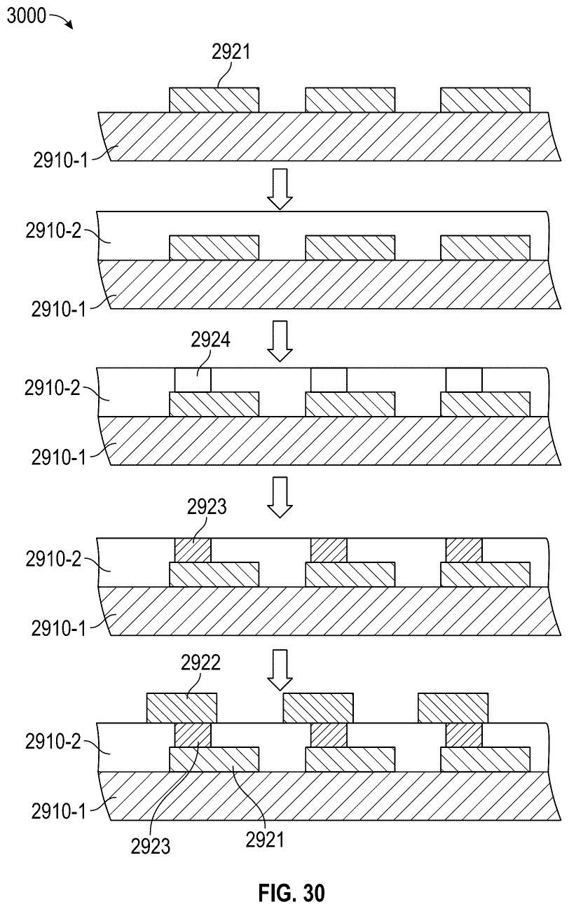

FIG. 30 is a flowchart illustrating a method 3000 for manufacturing another exemplary circuit of an electronic device, in accordance with some embodiments of the present disclosure. Method 3000 forms a first set of first circuit components 2921 on a first layer 2910-1 of the deformable substrate 2910 and then overlays a second layer 2910-2 on the first layer 2910-1, for instance, using a slot-die coating technique. The second layer 2910-2 encapsulates at least a portion of the first set of first circuit components 2921. The method then creates a set of channels 2924, for instance, using a laser or the like, through the second layer 2910-2. In some embodiments, each channel is extended to a first circuit component in the first set of the first circuit components. The set of channels is filled, for instance, using extrusion-based additive manufacturing method, such as direct printing techniques, with a composition of the present disclosure to form a third set of third circuit components 2923. In some embodiments, each third circuit component is a via. After that, the method forms a second set of second circuit components 2922 on the second layer 2910-2. In some embodiments, each second circuit in the second set of second circuit components 2922 contacts a third circuit component in the third set of third circuit components 2923.

In some embodiments, the first set of first circuit components 2921 consists of a single first circuit component. Alternatively, in some embodiments, the first set of first circuit components 2921 includes a number of first circuit components within a range of about 2 to 50 first circuit components. Similarly, in some embodiments, the second set of second circuit components 2922 consists of a single second circuit component. Alternatively, in some embodiments, the second set of second circuit components 2922 includes a number of second circuit components within a range of about 2 to 50 second circuit components. In some embodiments, the third set of third circuit components 2923 consists of a single third circuit component. Alternatively, in some embodiments, the third set of third circuit components 2923 includes a number of third circuit components within a range of about 2 to 50 third circuit components.

The line or via can be traced using, for instance, an extrusion-based additive manufacturing method such as direct printing techniques. Subsequent to the tracing, the polymeric binder or at least a portion of it polymerizes thereby forming the line or via that couples, and electrically connects, the first circuit component and second circuit component. For instance, in some embodiments, to obtain higher conductivity, after the tracing, the circuit is allowed to cure. In an embodiment, the circuit is allowed to cure at room temperature for a time within a range of about 4 to 24 hours. In another embodiment, the circuit is allowed to cure at an elevated temperature, for instance, between 40° C. to 80° C., for a time within a range of about 1 to 10 hours.

The at least one solvent can include any solvent or solvent mixture disclosed herein. For instance, in some embodiments, the at least one solvent includes a first solvent. In an embodiment, the first solvent includes toluene. In another embodiment, the first solvent includes TXIB. The polymeric binder can include any one or more polymers disclosed herein. For instance, in some embodiments, the polymeric binder includes a first polymer (block 1014). In an embodiment, the first polymer includes SEBS. In another embodiment, the first polymer includes SIS.

In some embodiments, the solution is composed of any one or more polymers (e.g., SIS, SEBS, silicone, or the like) dissolved in TXIB, or in a solvent mixture including TXIB. In some embodiments, the solution is composed of SEBS or a polymer mixture including SEBS dissolved in any solvent or solvent mixture. For instance, in some embodiments, the solution is a solution of SIS dissolved in TXIB, a solution of SIS dissolved in a mixture of TXIB and toluene, a solution of a polymer mixture including SIS dissolved in TXIB, a solution of SEBS dissolved in toluene, a solution of a polymer mixture including SEBS dissolved in toluene, or a solution of SEBS dissolved in a mixture of TXIB and toluene.

The liquid metal can be any liquid metal or liquid metal alloy disclosed herein. In some exemplary embodiments, the liquid metal is a Ga-based alloy.

In some embodiments, additionally or optionally, the composition further includes a metallic filler. Non-limiting examples of a metallic filler include, but not limited to, including but not limited to aluminum, titanium, cobalt, nickel, copper, zinc, silver, gold, or indium. In some embodiments, the metallic filler is in a form of microflakes, nanoflakes, microparticles, nanoparticles, nanowires, nanotubes, or a combination thereof.

In some embodiments, at least one of the first and second circuit components is made of a material different than the composition. For instance, in an embodiment, the first or second circuit component is a metal pad. In some embodiments, at least one of the first and second circuit components is made of a material substantially the same as the composition. For instance, in an embodiment, the first or second circuit component is a line or via made of the same composition.

In some embodiments, the first circuit component and the second circuit component form part of an active-matrix array. For instance, in some embodiments, the first circuit component or the second circuit component is a transistor, an electrode, or a capacitor disposed on the deformable substrate 2910, and the other of the first circuit component or the second circuit component is different than the transistor, the electrode, or the capacitor of the first circuit component or the second circuit component.

An aspect of the subject technology is directed to a method including forming a first circuit component at a first portion of a deformable substrate and forming a second circuit component at a second portion of the deformable substrate. The method further includes electronically coupling the first circuit component and the second circuit component using traces comprising a formulation including a liquid Ga-based alloy and a metal filler.

In some implementations, the deformable substrate comprises a layer or a portion made of a material having Young's Modulus higher than about 0.5 Gpa, and wherein the material includes at least one of polyethylene, polyetheretherketone (PEEK), polyester, aramid, composite, glass epoxy, and polyethylene naphthalate.

In one or more implementations, the liquid Ga-based alloy is characterized by a negative Gibbs free energy binding value and includes eutectic gallium-indium (EGaIn) and Galinstan, a metal alloy made of copper along with at least one or more metals including gallium, indium, or tin, or a nickel-titanium alloy.

In some implementations, the metal filler comprises an alloy including at least one of aluminum, silver, and wherein the metal filler comprises an amount within a range of 1 wt % to 2 wt % with respect to the liquid Ga-based alloy.

In one or more implementations, a Gibbs free energy binding value associated with the metal filler is less than a second Gibbs free energy binding value associated with the liquid Ga-based alloy.

In some implementations, the formulation further includes a binder including a thermoplastic elastomer.

In one or more implementations, the binder comprises at least one of thermoplastic polymer, cellulose, polyvinyl alcohol, polyacrylic acid, or polyvinylidene fluoride, polyvinyl acetate-polyvinylpyrrolidone, polyethylene glycol, amines, silicones, styrene isoprene styrene (SIS), or styrene ethylene butylene styrene (SEBS).

In some implementations, the first circuit component and the second circuit component include transistors, switches, electrodes, capacitors or logic gates.

In one or more implementations, the method further includes configuring a conductivity of the traces to allow forming the traces with a reduced cross-sectional area, and wherein the conductivity of the traces is configured to be greater than 3.4×106 Siemens per meter (S/m).

In some implementations, the method further includes providing corrosion resistivity by forming the formulation by using a water-resistant material including adding a low water-permeable elastomer to make the liquid Ga-based alloy.

In one or more implementations, the low water-permeable elastomer comprises at least one of silicone, medical grade polyurethane, polyethylene terephthalate (PET), polyimide (PI), polyphenylene sulfide (PPS) or a fluorine-containing resin.

Another aspect of the subject technology is directed to a device including a first circuit component formed at a first portion of a deformable substrate and a second circuit component formed at a second portion of the deformable substrate. The electronic device further includes a plurality of traces to electronically couple the first circuit component to the second circuit component. The traces comprise a formulation including a liquid Ga-based alloy and a metal filler.

In some implementations, the plurality of traces comprise conductive lines or vias, the deformable substrate comprises a material having a Young's Modulus higher than about 0.5 Gpa, and the material includes at least one of a list comprising polyethylene, PEEK, polyester, aramid, composite, glass epoxy, and polyethylene naphthalate.

In one or more implementations, the formulation further includes a binder comprising at least one of a list including thermoplastic polymer, cellulose, polyvinyl alcohol, polyacrylic acid or polyvinylidene fluoride.

In some implementations, the liquid Ga-based alloy comprises EGaIn and Galinstan, a metal alloy made of copper along with at least one or more metals of a list including gallium, indium, or tin, or a nickel-titanium alloy.

In one or more implementations, the deformable substrate, the first circuit component, the second circuit component and the plurality of traces are configured to form parts of a wearable device including a smart wristband or a smart glove.

Yet another aspect of the subject technology is directed to a method including forming a composition by providing a liquid solution including a Ga-based alloy including nanowires and mixing nanoparticles of a barrier material and a micro-powder with the liquid solution.

In one or more implementations, the barrier material comprises silver and the micro-powder includes tungsten (W), and wherein a size of the nanoparticles is about 100 nm.

In some implementations, the method further comprises using the composition to form a plurality of traces for electrically coupling two or more circuit components on a deformable substrate, and fabricating a wearable device including a smart wristband or a smart glove by using the deformable substrate including the plurality of traces and the two or more circuit components.

Yet another aspect of the subject technology is directed to a method including forming a first circuit component at a first portion of a deformable substrate, forming a second circuit component at a second portion of the deformable substrate. The method further includes tracing out at least one of a line or a via to couple the first circuit component and the second circuit component, with a composition comprising a solution with a polymer binder dissolved in at least one solvent and a liquid metal. Subsequent to the tracing out, the first polymer polymerizes thereby forming the line or the via that couples, and electronically connects, the first circuit component and the second circuit component.

In some implementations, the at least one solvent comprises a first solvent including toluene or 2,2,4-Trimethyl-1,3-pentanediol diisobutyrate (TXIB).

In one or more implementations, the polymer binder comprises a first polymer a polymer including SEBS or SIS.

In some implementations, the liquid metal comprises a Gallium-based ally and wherein the composition further includes a metallic filler.

In some implementations, the word “exemplary” is used herein to mean “serving as an example, instance, or illustration.” Any embodiment described herein as “exemplary” is not necessarily to be construed as preferred or advantageous over other embodiments. Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

A reference to an element in the singular is not intended to mean “one and only one” unless specifically stated, but rather “one or more.” Pronouns in the masculine (e.g., his) include the feminine and neuter gender (e.g., her and its) and vice versa. The term “some” refers to one or more. Underlined and/or italicized headings and subheadings are used for convenience only, do not limit the subject technology, and are not referred to in connection with the interpretation of the description of the subject technology. Relational terms such as first and second and the like may be used to distinguish one entity or action from another without necessarily requiring or implying any actual such relationship or order between such entities or actions. All structural and functional equivalents to the elements of the various configurations described throughout this disclosure that are known or later come to be known to those of ordinary skill in the art are expressly incorporated herein by reference and intended to be encompassed by the subject technology. Moreover, nothing disclosed herein is intended to be dedicated to the public, regardless of whether such disclosure is explicitly recited in the above description. No clause element is to be construed under the provisions of 35 U.S.C. § 112, sixth paragraph, unless the element is expressly recited using the phrase “means for” or, in the case of a method clause, the element is recited using the phrase “step for.”

While this specification contains many specifics, these should not be construed as limitations on the scope of what may be described, but rather as descriptions of particular implementations of the subject matter. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially described as such, one or more features from a described combination can in some cases be excised from the combination, and the described combination may be directed to a sub-combination or variation of a sub-combination.

The subject matter of this specification has been described in terms of particular aspects, but other aspects can be implemented and are within the scope of the following clauses. For example, while operations are depicted in the drawings in a particular order, this should not be understood as requiring that such operations be performed in the particular order shown or in sequential order, or that all illustrated operations be performed, to achieve desirable results. The actions recited in the clauses can be performed in a different order and still achieve desirable results. As one example, the processes depicted in the accompanying figures do not necessarily require the particular order shown, or sequential order, to achieve desirable results. In certain circumstances, multitasking and parallel processing may be advantageous. Moreover, the separation of various system components in the aspects described above should not be understood as requiring such separation in all aspects, and it should be understood that the described program components and systems can generally be integrated together in a single software product or packaged into multiple software products.

The title, background, brief description of the drawings, abstract, and drawings arc hereby incorporated into the disclosure and are provided as illustrative examples of the disclosure, not as restrictive descriptions. It is submitted with the understanding that they will not be used to limit the scope or meaning of the clauses. In addition, in the detailed description, it can be seen that the description provides illustrative examples, and the various features are grouped together in various implementations for the purpose of streamlining the disclosure. The method of disclosure is not to be interpreted as reflecting an intention that the described subject matter requires more features than are expressly recited in each clause. Rather, as the clauses reflect, inventive subject matter lies in less than all features of a single disclosed configuration or operation. The clauses are hereby incorporated into the detailed description, with each clause standing on its own as a separately described subject matter.

As used herein, the phrase “at least one of” preceding a series of items, with the terms “and” or “or” to separate any of the items, modifies the list as a whole, rather than each member of the list (i.e., each item).

To the extent that the term “include,” “have,” or the like is used in the description or the claims, such term is intended to be inclusive in a manner similar to the term “comprise” as “comprise” is interpreted when employed as a transitional word in a claim.

A reference to an element in the singular is not intended to mean “one and only one” unless specifically stated, but rather “one or more.” All structural and functional equivalents to the elements of the various configurations described throughout this disclosure that are known or later come to be known to those of ordinary skill in the art are expressly incorporated herein by reference and intended to be encompassed by the subject technology. Moreover, nothing disclosed herein is intended to be dedicated to the public regardless of whether such disclosure is explicitly recited in the above description.

While this specification contains many specifics, these should not be construed as limitations on the scope of what may be claimed, but rather as descriptions of particular implementations of the subject matter. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

What is claimed is:

1. A method comprising:
forming a first circuit component at a first portion of a deformable substrate;
forming a second circuit component at a second portion of the deformable substrate; and
electronically coupling the first circuit component and the second circuit component using traces including a formulation,
wherein the formulation includes a liquid Ga-based alloy and a metal filler.

2. The method of claim 1, wherein the deformable substrate comprises a layer or a portion made of a material having Young's Modulus higher than about 0.5 Gpa, and wherein the material includes at least one of polyethylene, polyetheretherketone (PEEK), polyester, aramid, composite, glass epoxy, and polyethylene naphthalate.

3. The method of claim 1, wherein the liquid Ga-based alloy is characterized by a negative Gibbs free energy binding value and includes eutectic gallium-indium (EGaIn) and Galinstan, a metal alloy made of copper along with at least one or more metals including gallium, indium, or tin, or a nickel-titanium alloy.

4. The method of claim 1, wherein the metal filler comprises an alloy including at least one of aluminum, silver, and wherein the metal filler comprises an amount within a range of 1 wt % to 2 wt % with respect to the liquid Ga-based alloy.

5. The method of claim 1, wherein a Gibbs free energy binding value associated with the metal filler is less than a second Gibbs free energy binding value associated with the liquid Ga-based alloy.

6. The method of claim 1, wherein the formulation further includes a binder including a thermoplastic elastomer.

7. The method of claim 6, wherein the binder comprises at least one of thermoplastic polymer, cellulose, polyvinyl alcohol, polyacrylic acid, or polyvinylidene fluoride, polyvinyl acetate-polyvinylpyrrolidone, polyethylene glycol, amines, silicones, styrene isoprene styrene (SIS), or styrene ethylene butylene styrene (SEBS).

8. The method of claim 1, wherein the first circuit component and the second circuit component include transistors, switches, electrodes, capacitors or logic gates.

9. The method of claim 8, further comprising configuring a conductivity of the traces to allow forming the traces with a reduced cross-sectional area, and wherein the conductivity of the traces is configured to be greater than 3.4×10⁶ Siemens per meter (S/m).

10. The method of claim 1, further comprising providing corrosion resistivity by forming the formulation by using a water-resistant material including adding a low water-permeable elastomer to make the liquid Ga-based alloy.

11. The method of claim 10, wherein the low water-permeable elastomer comprises at least one of silicone, medical grade polyurethane, polyethylene terephthalate (PET), polyimide (PI), polyphenylene sulfide (PPS) or a fluorine-containing resin.

12. An electronic device comprising:
a first circuit component formed at a first portion of a deformable substrate;
a second circuit component formed at a second portion of the deformable substrate; and
a plurality of traces configured to electronically couple the first circuit component to the second circuit component,
wherein the plurality of traces comprise a formulation including a liquid Ga-based alloy and a metal filler.

13. The electronic device of claim 12, wherein:
the plurality of traces comprise conductive lines or vias,
the deformable substrate comprises a material having a Young's Modulus higher than about 0.5 Gpa,
the material includes at least one of a list comprising polyethylene, PEEK, polyester, aramid, composite, glass epoxy, and polyethylene naphthalate.

14. The electronic device of claim 12, wherein:
the metal filler comprises an amount within a range of about 1 wt % to 2 wt % with respect to the liquid Ga-based alloy, and
the metal filler comprises an alloy including at least one of aluminum or silver.

15. The electronic device of claim 12, wherein the formulation further includes a binder comprising at least one of a list including thermoplastic polymer, cellulose, polyvinyl alcohol, polyacrylic acid or polyvinylidene fluoride.

16. The electronic device of claim 12, wherein the liquid Ga-based alloy comprises EGaIn and Galinstan, a metal alloy made of copper along with at least one or more metals of a list including gallium, indium, or tin, or a nickel-titanium alloy.

17. The electronic device of claim 12, wherein the deformable substrate, the first circuit component, the second circuit component and the plurality of traces are configured to form parts of a wearable device including a smart wristband or a smart glove.

18. A method comprising:
forming a composition by:
providing a liquid solution including a Ga-based alloy including nanowires; and
mixing nanoparticles of a barrier material and a micro-powder with the liquid solution.

19. The method of claim 18, wherein the barrier material comprises silver and the micro-powder includes tungsten (W), and wherein a size of the nanoparticles is about 100 nm.

20. The method of claim 18, further comprising:
using the composition to form a plurality of traces for electrically coupling two or more circuit components on a deformable substrate, and
fabricating a wearable device including a smart wristband or a smart glove by using the deformable substrate including the plurality of traces and the two or more circuit components.

21. A method comprising:
forming a first circuit component at a first portion of a deformable substrate;
forming a second circuit component at a second portion of the deformable substrate; and
tracing out at least one of a line or a via to couple the first circuit component and the second circuit component, with a composition comprising a solution with a polymer binder dissolved in at least one solvent and a liquid metal,
wherein subsequent to the tracing out, the polymer binder polymerizes thereby forming the line or the via that couples, and electronically connects, the first circuit component and the second circuit component.

22. The method of claim 21, wherein the at least one solvent comprises a first solvent including toluene or 2,2,4-Trimethyl-1,3-pentanediol diisobutyrate (TXIB).

23. The method of claim 21, wherein the polymer binder comprises a first polymer a polymer including styrene ethylene butylene styrene (SEBS), or SIS.

24. The method of claim 21, wherein the liquid metal comprises a Gallium-based ally and wherein the composition further includes a metallic filler.
